(19) United States
(12) Patent Application Publication
(10) Pub. No.: US 2026/0329542 A1
(43) Pub. Date: Oct. 22, 2026

(54) FLOATING-POINT ARITHMETIC USING HYBRID ANALOG-DIGITAL CIRCUITS

(71) Applicant: Koushik Krishnan, Saratoga, CA (US)

(72) Inventor: Koushik Krishnan, Saratoga, CA (US)

(21) Appl. No.: 19/639,331

(22) Filed: Apr. 6, 2026

Related U.S. Application Data
(60) Provisional application No. 63/791,110, filed on Apr. 18, 2025.
(60) Provisional application No. 63/819,003, filed on Jun. 6, 2025.

(51) Int. Cl. G06F 7/544; G06F 7/48; G06F 7/487

(52) U.S. Cl. CPC G06F 7/5443; G06F 7/4824; G06F 7/4876

(57) ABSTRACT

Circuits for floating-point arithmetic using hybrid analog-digital circuits are provided. A floating-point multiplier circuit comprises a signed floating-point digital-to-analog converter (S-FP-DAC) that receives a first sign bit and a first mantissa of a first floating-point operand. The S-FP-DAC comprises positive and negative current source banks with binary-weighted current sources, a mantissa storage, and sign-controlled switches that route current to an output based on the first sign bit to produce a signed current output. A pulse switch couples to the output. A pulse generation circuit generates a pulse signal with duration proportional to a second mantissa of a second floating-point operand. An integration circuit accumulates charge from the signed current output for the duration to produce a voltage signal proportional to the product of both mantissa representations. An analog-to-digital converter converts the voltage signal to a digital mantissa product.

### CROSS-REFERENCE TO RELATED APPLICATIONS/INCORPORATION BY REFERENCE

This application claims priority to U.S. Provisional Patent Application Ser. No. 63/791,110 filed on Apr. 18, 2025, and U.S. Provisional Patent Application Ser. No. 63/819,003 filed on Jun. 6, 2025, the entire content of which is hereby incorporated herein by reference.

### TECHNICAL FIELD

The disclosure relates to analog computing systems and more particularly, to technologies for performing floating-point arithmetic operations using hybrid analog-digital circuits.

### BACKGROUND

Computing systems have evolved to incorporate various architectures for performing arithmetic operations, including multiply-accumulate (MAC) and matrix-vector multiplication (MVM) operations. These operations are central to applications such as neural network inference, digital signal processing, and numerical modeling. As computational demands have increased, there has been growing interest in analog and mixed-signal computing techniques that can perform arithmetic operations by leveraging physical properties of circuits. Such approaches aim to reduce data movement, increase parallelism, and lower energy consumption by performing computations in the analog domain. Floating-point number representations present particular challenges for analog implementations due to the need to handle both the magnitude and sign of operands while maintaining precision across a wide dynamic range.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

In various embodiments of the disclosure, a floating-point multiplier circuit is described. The floating-point multiplier circuit includes a signed floating-point digital-to-analog converter (S-FP-DAC) configured to receive a first sign bit and a first mantissa of a first floating-point operand. The S-FP-DAC includes a positive current source bank having a first plurality of binary-weighted current sources. The S-FP-DAC further includes a negative current source bank having a second plurality of binary-weighted current sources. The S-FP-DAC also includes a mantissa storage configured to store a first mantissa representation of the first mantissa, wherein bits of the first mantissa representation selectively enable corresponding current sources in each of the positive current source bank and the negative current source bank to produce a positive current output and a negative current output, respectively. The S-FP-DAC additionally includes sign-controlled switches configured to route the positive current output or the negative current output to an output of the S-FP-DAC based on the first sign bit to produce a signed current output. The floating-point multiplier circuit further includes a pulse switch coupled to an output of the S-FP-DAC. The floating-point multiplier circuit also includes a pulse generation circuit configured to generate a pulse signal having a duration proportional to a second mantissa representation of a second mantissa of a second floating-point operand, wherein the pulse signal enables the pulse switch to allow a flow of the signed current output for the duration. The floating-point multiplier circuit additionally includes an integration circuit coupled to the pulse switch, wherein the integration circuit accumulates a charge from the flow of the signed current output for the duration to produce a voltage signal proportional to a product of the first mantissa representation and the second mantissa representation. The floating-point multiplier circuit further includes an analog-to-digital converter (ADC) configured to convert the voltage signal to a digital mantissa product.

In various embodiments of the disclosure, a floating-point multiply-accumulate (MAC) circuit is described. The floating-point MAC circuit includes a plurality of signed floating-point digital-to-analog converters (S-FP-DACs), wherein each S-FP-DAC of the plurality of S-FP-DACs is configured to receive a respective first sign bit and a respective first mantissa of a respective first floating-point operand of a first operand set, and produce a respective signed current output based on the respective first sign bit and the respective first mantissa. The floating-point MAC circuit further includes a plurality of pulse switches, wherein each pulse switch of the plurality of pulse switches is coupled to an output of a respective S-FP-DAC of the plurality of S-FP-DACs. The floating-point MAC circuit also includes a plurality of pulse generation circuits, wherein each pulse generation circuit of the plurality of pulse generation circuits is configured to generate a respective pulse signal based on a respective second mantissa of a respective second floating-point operand of a second operand set, and wherein each respective pulse signal enables a respective pulse switch of the plurality of pulse switches to allow a flow of the respective signed current output for a respective duration. The floating-point MAC circuit additionally includes an integration circuit coupled to the plurality of pulse switches, wherein the integration circuit accumulates charges from the flow of the respective signed current output of each S-FP-DAC of the plurality of S-FP-DACs for the respective duration to produce a voltage signal proportional to an accumulated product of pairwise mantissas of the first operand set and the second operand set. The floating-point MAC circuit further includes an analog-to-digital converter (ADC) configured to convert the voltage signal to a digital accumulated mantissa product.

The foregoing general description of the illustrative embodiments and the following detailed description thereof are merely exemplary aspects of the teachings of this disclosure and are not restrictive.

Additional technical features and benefits are realized through the techniques of the disclosure. Embodiments and aspects of the disclosure are described in detail herein and are considered a part of the claimed subject matter. For a better understanding, refer to the detailed description and the drawings.

### BRIEF DESCRIPTION OF THE DRAWINGS

The following description will provide details of preferred embodiments with reference to the following figures, wherein:

FIG. 1 is a diagram that illustrates a floating-point multiplier circuit configured to perform floating-point multiplication operations, in accordance with an embodiment of the disclosure;

FIG. 2 is a flowchart that illustrates a method for performing floating-point multiplication using a signed floating-point digital-to-analog converter, in accordance with an embodiment of the disclosure;

FIG. 3 is a diagram that illustrates a floating-point multiply-accumulate (MAC) circuit configured to perform multiply-accumulate operations on floating-point operands, in accordance with an embodiment of the disclosure;

FIGS. 4A, 4B, and 4C collectively illustrate a flowchart depicting a method for performing floating-point multiply-accumulate operations, in accordance with an embodiment of the disclosure;

FIG. 5 is a diagram that illustrates a floating-point adder circuit configured to perform floating-point addition operations using signed floating-point digital-to-analog converters, in accordance with an embodiment of the disclosure;

FIG. 6 is a block diagram that illustrates a floating-point multiplier circuit comprising a floating-point compute-in-memory circuit, in accordance with an embodiment of the disclosure; and

FIG. 7 is a diagram that illustrates a floating-point matrix-vector multiplication (MVM) circuit configured to perform matrix-vector multiplication operations on floating-point operands, in accordance with an embodiment of the disclosure.

### DETAILED DESCRIPTION

Digital computing systems have become fundamental components in modern technology, powering applications ranging from consumer electronics to industrial control systems. These systems rely on performing large numbers of arithmetic operations efficiently, particularly multiplication, multiply-accumulate (MAC), and matrix-vector multiplication (MVM) operations that form the core of many computational tasks. However, as computational demands continue to grow, conventional digital architectures face challenges in meeting performance and energy efficiency requirements.

Traditional digital systems typically separate processing units from memory units, creating a data transfer bottleneck that can lead to increased latency and power consumption. This separation becomes particularly problematic for data-intensive tasks that require frequent access to stored values, such as the multiplication operations commonly used in machine learning and signal processing applications. The phenomenon, often referred to as the “memory wall” in computer architecture literature, limits the effective speed of operation as data transport rather than processing element speed becomes the constraining factor.

Additionally, conventional digital multiplication units may be power-hungry, exhibiting lower operations per watt ratios compared to alternative approaches. As transistor scaling slows and simply increasing clock speeds or adding more processing cores becomes less effective at improving overall system performance, new computational paradigms are being explored to overcome these inherent limitations. Analog and mixed-signal computing techniques offer promising avenues for achieving high computational density and energy efficiency by leveraging the physical properties of circuits.

Floating-point arithmetic operations present additional challenges in the analog domain. A floating-point number consists of a sign bit (S), an exponent (EXP), and a mantissa (M). The value may be represented in scientific notation as S·(1+mantissa)·2^{(Exp-BIAS)}, where S is the sign, Exp is the exponent, and BIAS is a bias value used to represent negative exponents. The mantissa includes an implicit leading one bit, which is not stored but assumed during computation. For instance, in FP16 format, the exponent is 5 bits and the mantissa is 10 bits, while BF16 format uses an 8-bit exponent and a 7-bit mantissa, offering a higher dynamic range. The exponent uses a bias to split the full range of exponent bits to half for positive values and half for negative values.

The present disclosure describes a hybrid analog-digital approach that addresses these challenges through current-time domain processing techniques for performing floating-point multiplication and multiply-accumulate operations. The approach may utilize signed floating-point digital-to-analog converters (S-FP-DACs) that incorporate both positive and negative current source banks to handle signed floating-point representations. The S-FP-DAC architecture may include mantissa storage with shift register capability, sign-controlled switches for routing positive or negative current outputs based on sign bits, and enable switches for selective activation of DAC elements.

To achieve multiplication of two floating-point operands, the implementation may involve three main operations. First, exponent addition may be performed digitally, where the exponents of the two operands are added with bias correction applied to maintain IEEE 754 compliance: EXP(Yᵢ)=EXP(xᵢ)+EXP(wᵢ)−B. Second, sign calculation may be performed by computing an exclusive-OR operation on the sign bits of the operands: S(Yᵢ)=S(xᵢ)⊕S(wᵢ). Third, mantissa multiplication may be performed via an IT-DAC method, where the mantissas with their implicit leading one bits restored are multiplied: Mantissa (Yᵢ)=(1+M(xᵢ))·(1+M(wᵢ))−1. This analog multiplication may be realized by extending the precision of the input mantissas by one bit and using current sources combined with pulse-width modulation to compute the product. For standalone multiplication operations, the shift register capability may not be used, as shifting is primarily required when addition or accumulation is involved for exponent alignment purposes.

For multiply-accumulate operations, the approach may extend to handle multiple operand pairs. The MAC procedure may involve computing product exponents digitally for each multiplication pair, determining a maximum exponent among all products to be accumulated, and aligning mantissas by right-shifting based on the difference between the maximum exponent and each respective product exponent. The aligned mantissas may then be multiplied and accumulated in the analog domain using the IT-DAC method, enabling efficient analog computation of floating-point MAC operations. For MAC operations, shifting may be performed before multiplication begins, not after, because the addition requires aligned exponents.

The hybrid analog-digital approach may offer several advantages over existing digital and analog implementations. In terms of data movement, the approach may reduce the frequency of data transfers between memory and processing units by performing computations directly in the analog domain, often in close proximity to memory. The approach may increase parallelism by enabling multiple multiplication operations to be performed simultaneously through parallel S-FP-DAC structures with shared integration circuitry.

Power efficiency may be substantially improved compared to conventional digital implementations. The approach may provide better efficiency than traditional digital multiplication units, measured in operations per watt. This improvement may result from performing mantissa multiplication operations in the analog domain while maintaining the robustness and precision characteristics of digital systems through the use of digital inputs and outputs for exponent and sign processing.

Area efficiency may also be enhanced, with the approach potentially requiring smaller area overhead compared to digital in-memory compute or near-memory compute implementations. This reduction in area requirements may translate to higher computational density, allowing for more compact and efficient chip designs that can accommodate more processing elements within the same silicon area.

The system may support multiple floating-point precision formats to accommodate different application requirements. The approach may be configured for FP8, FP16, and BF16 operations, allowing designers to optimize the trade-off between precision, dynamic range, and power consumption based on specific computational needs. The exponent handling may be performed entirely in the digital domain using simple addition and subtraction operations, while the mantissa multiplication may be performed in the analog domain using current sources and pulse-width modulation techniques. For FP8 format with a 3-bit mantissa, the result of FP8 times FP8 produces an exponent of 4 plus 4 equals 5 bits with possible overflow by 1 bit, and the mantissa product is (1+3) times (1+3) equals 4 times 4 equals 8 bits, represented as 1+7 bits, requiring total internal precision of 13 bits.

The scalability of the approach with technology nodes may provide continued performance improvements as semiconductor manufacturing processes evolve. The current-time domain processing method may leverage advances in digital circuit performance, particularly in pulse width modulation generation and switching speeds, while the analog mantissa multiplication may benefit from improved current source matching in advanced process nodes.

The versatility of the approach may enable deployment across diverse application domains. The system may be targeted for accelerator or primary processor applications where high-speed floating-point multiplication and multiply-accumulate operations are required. The approach may be suitable for both training and inference applications in machine learning systems, supporting the computational demands of neural network processing where floating-point multiplication and multiply-accumulate operations are prevalent. Memory integration capabilities may enable the approach to be deployed in memory chips with in-memory or near-memory processing devices, bringing computation closer to data storage to reduce data movement overhead.

In various embodiments of the disclosure, a floating-point multiplier circuit is described. The floating-point multiplier circuit includes a signed floating-point digital-to-analog converter (S-FP-DAC) configured to receive a first sign bit and a first mantissa of a first floating-point operand. The S-FP-DAC includes a positive current source bank having a first plurality of binary-weighted current sources. The S-FP-DAC further includes a negative current source bank having a second plurality of binary-weighted current sources. The S-FP-DAC further includes a mantissa storage configured to store a first mantissa representation of the first mantissa. Bits of the first mantissa representation selectively enable corresponding current sources in each of the positive current source bank and the negative current source bank to produce a positive current output and a negative current output, respectively. The S-FP-DAC further includes sign-controlled switches configured to route the positive current output or the negative current output to an output of the S-FP-DAC based on the first sign bit to produce a signed current output. The floating-point multiplier circuit further includes a pulse switch coupled to an output of the S-FP-DAC. The floating-point multiplier circuit further includes a pulse generation circuit configured to generate a pulse signal having a duration proportional to a second mantissa representation of a second mantissa of a second floating-point operand. The pulse signal enables the pulse switch to allow a flow of the signed current output for the duration. The floating-point multiplier circuit further includes an integration circuit coupled to the pulse switch. The integration circuit accumulates a charge from the flow of the signed current output for the duration to produce a voltage signal proportional to a product of the first mantissa representation and the second mantissa representation. The floating-point multiplier circuit further includes an analog-to-digital converter (ADC) configured to convert the voltage signal to a digital mantissa product.

In various embodiments of the disclosure, the first mantissa representation includes an implicit leading one bit prepended to the first mantissa, and the second mantissa representation includes an implicit leading one bit prepended to the second mantissa.

In various embodiments of the disclosure, the floating-point multiplier circuit further includes a digital processing circuit configured to compute a product exponent by adding a first exponent of the first floating-point operand and a second exponent of the second floating-point operand. The digital processing circuit is further configured to apply a bias correction to the product exponent to obtain updated product exponent.

In various embodiments of the disclosure, the digital processing circuit is further configured to perform an exclusive-OR operation on the first sign bit and a second sign bit of the second floating-point operand to compute a product sign bit.

In various embodiments of the disclosure, the digital processing circuit is further configured to reconstruct a floating-point product of the first floating-point operand and the second floating-point operand in an IEEE floating-point format based on the updated product exponent, the product sign bit, and the digital mantissa product.

In various embodiments of the disclosure, the integration circuit includes a capacitor coupled between the pulse generation circuit and a reference ground terminal. The voltage signal is across the capacitor.

In various embodiments of the disclosure, each of the first floating-point operand and the second floating-point operand is a binary number that follows IEEE 754 standard.

In various embodiments of the disclosure, the sign-controlled switches are configured to route the positive current output to the output of the S-FP-DAC based on the first sign bit indicating a positive value of the first floating-point operand. The sign-controlled switches are further configured to route the negative current output to the output of the S-FP-DAC based on the first sign bit indicating a negative value of the first floating-point operand.

In various embodiments of the disclosure, the second mantissa representation is an unsigned mantissa representation. The sign-controlled switches are further configured to route the positive current output or the negative current output based on a second sign bit of the second floating-point operand.

In various embodiments of the disclosure, a floating-point multiply-accumulate (MAC) circuit is described. The floating-point MAC circuit includes a plurality of signed floating-point digital-to-analog converters (S-FP-DACs). Each S-FP-DAC of the plurality of S-FP-DACs is configured to receive a respective first sign bit and a respective first mantissa of a respective first floating-point operand of a first operand set. Each S-FP-DAC is further configured to produce a respective signed current output based on the respective first sign bit and the respective first mantissa. The floating-point MAC circuit further includes a plurality of pulse switches. Each pulse switch of the plurality of pulse switches is coupled to an output of a respective S-FP-DAC of the plurality of S-FP-DACs. The floating-point MAC circuit further includes a plurality of pulse generation circuits. Each pulse generation circuit of the plurality of pulse generation circuits is configured to generate a respective pulse signal based on a respective second mantissa of a respective second floating-point operand of a second operand set. Each respective pulse signal enables a respective pulse switch of the plurality of pulse switches to allow a flow of the respective signed current output for a respective duration. The floating-point MAC circuit further includes an integration circuit coupled to the plurality of pulse switches. The integration circuit accumulates charges from the flow of the respective signed current output of each S-FP-DAC of the plurality of S-FP-DACs for the respective duration to produce a voltage signal proportional to an accumulated product of pairwise mantissas of the first operand set and the second operand set. The floating-point MAC circuit further includes an analog-to-digital converter (ADC) configured to convert the voltage signal to a digital accumulated mantissa product.

In various embodiments of the disclosure, each S-FP-DAC of the plurality of S-FP-DACs includes a positive current source bank and a negative current source bank.

In various embodiments of the disclosure, the positive current source bank includes a first plurality of binary-weighted current sources and the negative current source bank includes a second plurality of binary-weighted current sources.

In various embodiments of the disclosure, each S-FP-DAC of the plurality of S-FP-DACs includes a mantissa storage configured to store a respective first mantissa representation of the respective first mantissa. Bits of the respective first mantissa representation selectively enable corresponding current sources in the positive current source bank and the negative current source bank to produce a positive current output and a negative current output, respectively.

In various embodiments of the disclosure, the respective first mantissa representation includes an implicit leading one bit prepended to bits of the respective first mantissa.

In various embodiments of the disclosure, each S-FP-DAC of the plurality of S-FP-DACs includes sign-controlled switches configured to route the positive current output or the negative current output to the output of the respective S-FP-DAC based on the respective first sign bit to produce the respective signed current output.

In various embodiments of the disclosure, the mantissa storage includes a shift register configured to perform right-shift operations on the bits of the respective first mantissa representation based on clock signals. The right-shift operations shift a zero bit into a most significant bit position of the respective first mantissa representation for each clock cycle of the clock signals.

In various embodiments of the disclosure, the floating-point MAC circuit further includes a digital processing circuit configured to compute each product exponent of a plurality of respective product exponents for a pair of the respective first floating-point operand and the respective second floating-point operand by adding a respective first exponent of the respective first floating-point operand and a respective second exponent of the respective second floating-point operand. The digital processing circuit is further configured to determine a maximum exponent among the plurality of respective product exponents. The digital processing circuit is further configured to generate the clock signals for each S-FP-DAC of the plurality of S-FP-DACs based on a difference between the maximum exponent and a respective product exponent of the plurality of respective product exponents.

In various embodiments of the disclosure, the digital processing circuit is further configured to apply a number of clock cycles of the clock signals to each S-FP-DAC of the plurality of S-FP-DACs. The number of clock cycles equals the difference between the maximum exponent and the respective product exponent for the respective S-FP-DAC.

In various embodiments of the disclosure, the digital processing circuit is further configured to perform an exclusive-OR operation on the respective first sign bit and a respective second sign bit of the respective second floating-point operand to compute a respective product sign bit for the respective first floating-point operand and the respective second floating-point operand. The digital processing circuit is further configured to generate a respective control signal for each S-FP-DAC of the plurality of S-FP-DACs based on the respective product sign bit. The sign-controlled switches of each S-FP-DAC are configured to selectively invert routing of the positive current output and the negative current output based on the respective control signal.

In various embodiments of the disclosure, each S-FP-DAC of the plurality of S-FP-DACs further includes an enable switch configured to selectively connect or disconnect the respective signed current output from the integration circuit based on a respective enable signal.

In various embodiments of the disclosure, the digital processing circuit is further configured to group the plurality of S-FP-DACs into a plurality of groups based on the plurality of respective product exponents. Each group of the plurality of groups includes a subset of S-FP-DACs of the plurality of S-FP-DACs. The subset of S-FP-DACs have respective product exponents within a predetermined range. The digital processing circuit is further configured to generate the respective enable signal for each S-FP-DAC of the plurality of S-FP-DACs to enable the subset of S-FP-DACs and disable S-FP-DACs of the plurality of S-FP-DACs different from the subset of S-FP-DACs.

In various embodiments of the disclosure, the respective pulse signal is generated with a respective pulse duration proportional to a respective second mantissa representation of the respective second mantissa. The respective second mantissa representation is an unsigned value. The respective second mantissa representation includes an implicit leading one bit prepended to bits of the respective second mantissa.

In various embodiments of the disclosure, the integration circuit includes a capacitor. The voltage signal is across the capacitor as a sum of charges accumulated from the flow of the respective signed current output of each S-FP-DAC of the plurality of S-FP-DACs for the respective duration.

The following description sets forth exemplary aspects of the present disclosure. It should be recognized, however, that such description is not intended as a limitation on the scope of the present disclosure. Rather, the description also encompasses combinations and modifications to those exemplary aspects described herein.

A detailed description of systems, devices, and methods consistent with embodiments of the present disclosure is provided below. While several embodiments are described, it should be understood that disclosure is not limited to any one embodiment, but instead encompasses numerous alternatives, modifications, and equivalents. In addition, while numerous specific details are set forth in the following description in order to provide a thorough understanding of the embodiments disclosed herein, some embodiments can be practiced without some or all of these details. Moreover, for the purpose of clarity, certain technical material that is known in the related art has not been described in detail in order to avoid unnecessarily obscuring the disclosure.

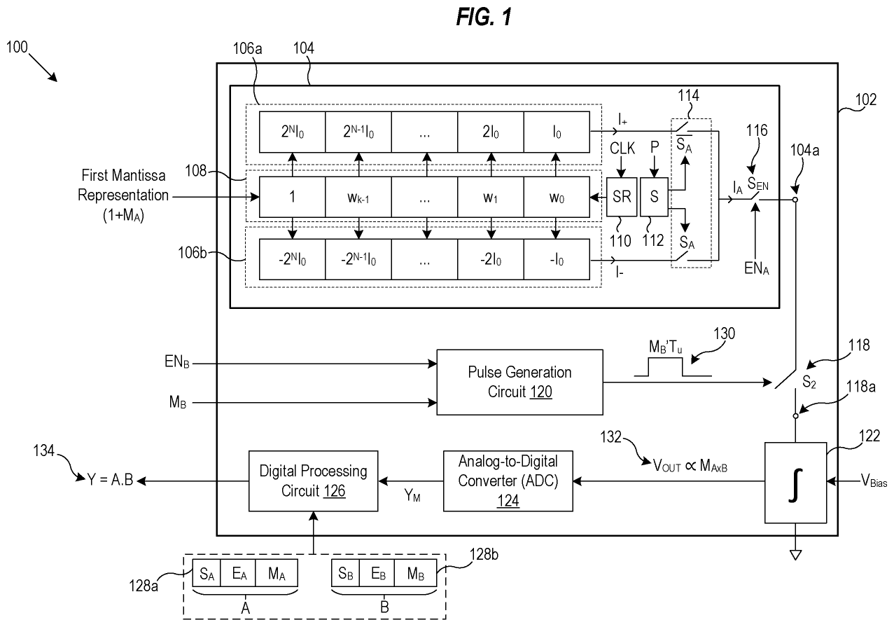

FIG. 1 is a diagram 100 that illustrates a floating-point multiplier circuit 102 configured to perform floating-point multiplication operations, in accordance with an embodiment of the disclosure. The floating-point multiplier circuit 102 comprises a signed floating-point digital-to-analog converter (S-FP-DAC) 104, a pulse switch 118, a pulse generation circuit 120, an integration circuit 122, an analog-to-digital converter (ADC) 124, and a digital processing circuit 126. The floating-point multiplier circuit 102 is configured to receive a first floating-point operand 128a and a second floating-point operand 128b and produce a floating-point product 134 representing a multiplication result of the first floating-point operand 128a and the second floating-point operand 128b. In various embodiments, the floating-point multiplier circuit 102 may be implemented as a standalone multiplication unit, as part of a larger compute-in-memory (CIM) architecture, or integrated within a neural network accelerator. The floating-point multiplier circuit 102 may be fabricated using complementary metal-oxide-semiconductor (CMOS) technology, bipolar junction transistor (BJT) technology, or other suitable semiconductor fabrication processes.

The signed floating-point digital-to-analog converter 104 is configured to receive a first sign bit and a first mantissa of the first floating-point operand 128a. The signed floating-point digital-to-analog converter 104 comprises a positive current source bank 106a having a first plurality of binary-weighted current sources and a negative current source bank 106b having a second plurality of binary-weighted current sources. The positive current source bank 106a and the negative current source bank 106b are arranged in parallel. The first plurality of binary-weighted current sources of the positive current source bank 106a is labeled from 2^{N}×I₀ down to I₀, where I₀ represents a unit current value and N represents the number of mantissa bits. The second plurality of binary-weighted current sources of the negative current source bank 106b is labeled from −2^{N}×I₀ down to −I₀, providing corresponding negative current values for each binary weight position. The binary weighting of the current sources enables direct conversion of the mantissa bits to proportional current magnitudes, where each bit position controls a current source with magnitude proportional to its positional weight. The total output current from the positive current source bank 106a or the negative current source bank 106b represents (1+mantissa)×I₀, where the implicit leading one bit corresponds to the always-on most significant bit current source. The current sources may be implemented using current mirror circuits, cascode current sources, regulated cascode current sources, or other current source topologies known in the art. In some embodiments, the current sources may be implemented using PMOS transistors for the positive current source bank 106a and NMOS transistors for the negative current source bank 106b, or vice versa depending on the supply voltage configuration and output swing requirements.

With continued reference to FIG. 1, the signed floating-point digital-to-analog converter 104 further comprises a mantissa storage 108 positioned between the positive current source bank 106a and the negative current source bank 106b. The mantissa storage 108 is configured to store a first mantissa representation of the first mantissa. The first mantissa representation comprises an implicit leading one bit prepended to the first mantissa. For a 3-bit mantissa (M₂, M₁, M₀), the mantissa storage 108 stores a 4-bit value represented as {1, M₂, M₁, M₀}, where the leading one bit corresponds to the implicit leading one in IEEE floating-point representation. The mantissa storage 108 stores mantissa bits wₖ₋₁ through w₀ along with the implicit leading one bit. Bits of the first mantissa representation selectively enable corresponding current sources in each of the positive current source bank 106a and the negative current source bank 106b to produce a positive current output I+ and a negative current output I−, respectively. In various embodiments, the mantissa storage 108 may be implemented using static random-access memory (SRAM) cells, dynamic random-access memory (DRAM) cells, flip-flops, latches, or non-volatile memory elements such as resistive random-access memory (ReRAM), phase-change memory (PCM), or magnetoresistive random-access memory (MRAM). For example, in an embodiment targeting FP8 format with a 3-bit mantissa, the mantissa storage 108 may comprise four storage elements to store the 4-bit value {1, M₂, M₁, M₀}. In an embodiment targeting FP16 format with a 10-bit mantissa, the mantissa storage 108 may comprise eleven storage elements to store the 11-bit value {1, M₉, M₈, . . . , M₁, M₀}. In an embodiment targeting BF16 format with a 7-bit mantissa, the mantissa storage 108 may comprise eight storage elements to store the 8-bit value {1, M₆, M₅, . . . , M₁, M₀}.

The mantissa storage 108 comprises a shift register 110 configured to perform right-shift operations on bits of the first mantissa representation based on clock signals CLK. The shift register 110 enables exponent alignment for multiply-accumulate operations by shifting the first mantissa representation to account for exponent differences between operands. The right-shift operations shift a zero bit into a most significant bit position of the first mantissa representation for each clock cycle of the clock signals. On each clock cycle of the clock signals, the shift register 110 shifts bits from the most significant bit position toward the least significant bit position, with a zero bit (X₀=0) shifted into the most significant bit position. Bits shifted out from the least significant bit position are discarded, resulting in a lower precision representation of the same value. The number of clock cycles applied to the shift register 110 determines the shift amount, which equals the exponent difference when aligning operands for accumulation. By removing the clock signal and holding it static, the shifting of bits stops. In various embodiments, the shift register 110 may be implemented using D flip-flops, JK flip-flops, or other sequential logic elements. The shift register 110 may be configured as a serial-in serial-out (SISO) shift register, a parallel-in serial-out (PISO) shift register, or a parallel-in parallel-out (PIPO) shift register with shift capability. In some embodiments, the shift register 110 may support bidirectional shifting to enable both right-shift and left-shift operations, although right-shift operations are primarily used for exponent alignment. The clock signals CLK may be generated by a dedicated clock generation circuit, derived from a system clock, or provided by the digital processing circuit 126. In an alternative embodiment, the shift register 110 may be replaced by a barrel shifter that performs the shift operation in a single clock cycle rather than multiple clock cycles, trading off area for speed.

The signed floating-point digital-to-analog converter 104 further comprises a sign bit storage 112 configured to store the first sign bit S_{A} of the first floating-point operand 128a. The sign bit storage 112 provides the sign information to sign-controlled switches 114 for routing the appropriate current output based on the first sign bit. The signed floating-point digital-to-analog converter 104 implements a one's complement representation for signed numbers, where the first sign bit controls whether the output represents a positive value or a negative value. In various embodiments, the sign bit storage 112 may be implemented using a single flip-flop, a latch, an SRAM cell, or other suitable storage element. In some embodiments, the sign bit storage 112 may be integrated with the mantissa storage 108 as part of a unified storage structure. In alternative embodiments, the signed floating-point digital-to-analog converter 104 may implement a two's complement representation instead of a one's complement representation, with appropriate modifications to the sign-controlled switches 114 and current source configurations.

As shown in FIG. 1, the signed floating-point digital-to-analog converter 104 further comprises sign-controlled switches 114 coupled to the positive current source bank 106a and the negative current source bank 106b. The sign-controlled switches 114 are configured to route the positive current output I+ or the negative current output I− to an output 104a of the signed floating-point digital-to-analog converter 104 based on the first sign bit S_{A} to produce a signed current output. The sign-controlled switches 114 are configured to route the positive current output to the output 104a of the S-FP-DAC 104 based on the first sign bit indicating a positive value of the first floating-point operand 128a. When the first sign bit equals zero, indicating a positive value of the first floating-point operand 128a, the sign-controlled switches 114 close the switch to the positive current source bank 106a and route the positive current output I+ to the output 104a. The sign-controlled switches 114 are further configured to route the negative current output to the output 104a of the S-FP-DAC 104 based on the first sign bit indicating a negative value of the first floating-point operand 128a. When the first sign bit equals one, indicating a negative value of the first floating-point operand 128a, the sign-controlled switches 114 close the switch to the negative current source bank 106b and route the negative current output I− to the output 104a. The sign-controlled switches 114 produce a signed current output I_{A} that represents the signed mantissa value of the first floating-point operand 128a. In various embodiments, the sign-controlled switches 114 may be implemented using transmission gates, CMOS pass transistors, NMOS-only switches, PMOS-only switches, or other switching elements. For example, in a low-power embodiment, the sign-controlled switches 114 may be implemented using minimum-sized transmission gates to reduce parasitic capacitance and switching energy. In a high-speed embodiment, the sign-controlled switches 114 may be implemented using larger transistors with lower on-resistance to minimize signal propagation delay. In some embodiments, the sign-controlled switches 114 may include complementary switch pairs that ensure one path is always closed while the other is open, preventing floating outputs and reducing glitch energy.

The signed floating-point digital-to-analog converter 104 further comprises a control signal P that enables support for subtraction operations by selectively inverting the first sign bit. When the control signal P equals one, the first sign bit is inverted to represent a subtraction operation, effectively computing A+ (−B) instead of A+B, where NOT(S_{A}) represents subtraction. When the control signal P equals zero, the first sign bit is not inverted, representing an addition operation. The control signal P provides flexibility for implementing both addition and subtraction operations using the same hardware structure. The sign-controlled switches 114 are further configured to route the positive current output or the negative current output based on a second sign bit of the second floating-point operand 128b when the second mantissa representation is an unsigned mantissa representation. The switches for S_{A} and ENA are interchangeable in position within the circuit. In various embodiments, the control signal P may be generated by the digital processing circuit 126 based on the operation being performed, or may be provided as an external control input. In some embodiments, the control signal P may be combined with the first sign bit using an exclusive-OR gate before being provided to the sign-controlled switches 114, enabling a single control path for both addition and subtraction operations.

With continued reference to FIG. 1, an enable switch 116 is coupled to the output 104a of the signed floating-point digital-to-analog converter 104. The enable switch 116 is configured to selectively connect or disconnect the signed current output I_{A} from the integration circuit 122 based on an enable signal ENA. When the enable signal ENA equals one, the enable switch 116 connects the signed current output I_{A} to allow current flow to the integration circuit 122. When the enable signal ENA equals zero, the enable switch 116 disconnects the signed current output I_{A}, preventing current flow and excluding the signed floating-point digital-to-analog converter 104 from participating in the computation, such that the DAC element does not output any current. The enable switch 116 enables selective activation of DAC elements based on exponent grouping during multiply-accumulate operations. In various embodiments, the enable switch 116 may be implemented using a transmission gate, a CMOS pass transistor, a tri-state buffer, or other switching elements. In some embodiments, the enable switch 116 may be positioned before the sign-controlled switches 114 rather than after, with equivalent functional behavior. In alternative embodiments, the enable functionality may be implemented by gating the current sources directly rather than using a separate enable switch 116, which may reduce the number of series switches in the current path and improve current source accuracy.

The pulse switch 118 is coupled to an output 118a of the S-FP-DAC 104 and receives the signed current output from the enable switch 116. The pulse generation circuit 120 is configured to receive a second mantissa M_{B} of the second floating-point operand 128b and an enable signal ENB. The pulse generation circuit 120 is configured to generate a pulse signal 130 having a duration proportional to a second mantissa representation of the second mantissa of the second floating-point operand 128b. The duration is expressed as M_{B}′×Tᵤ, where Tᵤ represents a unit time value and M_{B}′=2^{B}+M_{B} represents the second mantissa representation with the implicit leading one bit. The second mantissa representation comprises an implicit leading one bit prepended to the second mantissa, making the second mantissa representation an unsigned mantissa representation. The pulse signal 130 enables the pulse switch 118 to allow a flow of the signed current output for the duration. The pulse signal 130 controls the pulse switch 118 via a switch S₂ to allow the flow of the signed current output for the duration of the pulse signal 130. In various embodiments, the pulse generation circuit 120 may be implemented using a digital counter, a delay line, a ramp-and-compare circuit, a pulse-width modulation (PWM) generator, or other timing circuit topologies. For example, in a counter-based embodiment, the pulse generation circuit 120 may comprise a digital counter that counts from zero to the second mantissa representation value, with the pulse signal 130 being high during the counting period. In a delay-line-based embodiment, the pulse generation circuit 120 may comprise a chain of delay elements with taps corresponding to different mantissa bit positions. The unit time value Tᵤ may range from approximately 100 picoseconds to 100 nanoseconds, depending on the target throughput and precision requirements. In some embodiments, the pulse generation circuit 120 may include calibration circuitry to compensate for process, voltage, and temperature (PVT) variations in the pulse duration.

The integration circuit 122 is coupled to the pulse switch 118. The integration circuit 122 comprises a capacitor coupled between the pulse generation circuit 120 and a reference ground terminal. The capacitor is also connected to a bias voltage V_{Bias} (also referred to as V_{MID}). The integration circuit 122 accumulates a charge from the flow of the signed current output for the duration to produce a voltage signal 132 proportional to a product of the first mantissa representation and the second mantissa representation. The voltage signal 132 is across the capacitor and is expressed as V_{OUT} proportional to M_{A×B}. The mathematical relationship for the integration operation may be expressed as Vₒᵤₜ=I×Y/C, where I represents the current magnitude determined by the first mantissa representation, T represents the pulse duration determined by the second mantissa representation, and C represents the capacitance value of the integration circuit 122. The capacitor may be implemented using metal-insulator-metal (MIM) capacitors, metal-oxide-metal (MOM) capacitors, polysilicon capacitors, or other capacitor structures available in the fabrication process. In some embodiments, the integration circuit 122 may include a reset switch to discharge the capacitor before each multiplication operation. In alternative embodiments, the integration circuit 122 may comprise an operational amplifier-based integrator, providing improved linearity and output impedance compared to a passive capacitor-based integrator.

The analog-to-digital converter (ADC) 124 is coupled to the integration circuit 122 and is configured to receive the voltage signal 132. The analog-to-digital converter 124 is configured to convert the voltage signal 132 to a digital mantissa product Y_{M} representing the result of the mantissa multiplication in digital form. The analog-to-digital converter 124 may be implemented using various ADC architectures, including successive approximation register (SAR) ADCs, sigma-delta ADCs, flash ADCs, or pipeline ADCs, depending on speed, precision, and power consumption requirements. The ADC 124 extracts extra bits to account for signed operations and overflow conditions. In various embodiments, the analog-to-digital converter 124 may have a resolution ranging from 8 bits to 16 bits, depending on the target floating-point format and precision requirements. For example, in an embodiment targeting FP8 format with a 3-bit mantissa, the analog-to-digital converter 124 may have a resolution of 8 bits to capture the product of two 4-bit mantissa representations (including implicit leading ones) with sufficient precision. In an embodiment targeting FP16 format with a 10-bit mantissa, the analog-to-digital converter 124 may have a resolution of 12 to 14 bits. The analog-to-digital converter 124 may include input range scaling circuitry to accommodate both positive and negative voltage signals corresponding to signed mantissa products. In some embodiments, the analog-to-digital converter 124 may be shared among multiple floating-point multiplier circuits 102 using time-division multiplexing to reduce area overhead.

As further shown in FIG. 1, the digital processing circuit 126 is coupled to the analog-to-digital converter 124 and is configured to receive the digital mantissa product Y_{M}. The digital processing circuit 126 is configured to compute a product exponent by adding a first exponent of the first floating-point operand 128a and a second exponent of the second floating-point operand 128b. The digital processing circuit 126 is further configured to apply a bias correction to the product exponent to obtain an updated product exponent to maintain IEEE 754 compliance, expressed as EXP(Y)=EXP(A)+EXP(B)−B, where B represents the bias value. The digital processing circuit 126 is further configured to perform an exclusive-OR operation on the first sign bit and a second sign bit of the second floating-point operand 128b to compute a product sign bit, expressed as S(Y)=S(A)⊕S(B). The digital processing circuit 126 is further configured to reconstruct a floating-point product 134 of the first floating-point operand 128a and the second floating-point operand 128b in an IEEE floating-point format based on the updated product exponent, the product sign bit, and the digital mantissa product. The floating-point product 134 is denoted as Y=A×B. The mantissa computation follows the relationship M_{CC}=(1+M_{A})×(1+M_{B}), where the first term (1+M_{A}) is stored in the S-FP-DAC 104 as current magnitude and the second term (1+M_{B}) represents the pulse signal duration. In various embodiments, the digital processing circuit 126 may be implemented using combinational logic gates, a microcontroller, a digital signal processor (DSP), a field-programmable gate array (FPGA), or an application-specific integrated circuit (ASIC). The digital processing circuit 126 may include normalization logic to shift the digital mantissa product and adjust the updated product exponent when the product mantissa exceeds the representable range. The digital processing circuit 126 may also include overflow and underflow detection logic to handle exceptional conditions. In some embodiments, the digital processing circuit 126 may support multiple floating-point formats (e.g., FP8, FP16, BF16, FP32) with configurable bias values and mantissa widths.

The floating-point multiplier circuit 102 separates digital domain processing of exponents and sign bits from analog domain processing of mantissas. The exponent computation and sign calculation are performed entirely in the digital domain using simple addition, subtraction, and exclusive-OR operations, and do not require intensive multiply operations. The mantissa multiplication is performed in the analog domain using the current sources and pulse-width modulation techniques of the signed floating-point digital-to-analog converter 104 and the pulse generation circuit 120. The analog-to-digital converter 124 provides the interface between the analog mantissa multiplication result and the digital reconstruction of the final floating-point product 134.

Each of the first floating-point operand 128a and the second floating-point operand 128b is a binary number that follows the IEEE 754 standard. In various embodiments, the floating-point multiplier circuit 102 may support FP8 format (1 sign bit, 4 exponent bits, 3 mantissa bits), FP16 format (1 sign bit, 5 exponent bits, 10 mantissa bits), BF16 format (1 sign bit, 8 exponent bits, 7 mantissa bits), or other floating-point formats. The floating-point multiplier circuit 102 may be deployed in various applications including neural network inference accelerators, neural network training accelerators, digital signal processing systems, scientific computing systems, and graphics processing units. In some embodiments, multiple instances of the floating-point multiplier circuit 102 may be arranged in parallel to form a vector multiplication unit or a matrix multiplication unit. In alternative embodiments, the floating-point multiplier circuit 102 may be integrated with memory arrays to form a compute-in-memory or near-memory computing architecture, reducing data movement overhead between memory and processing units.

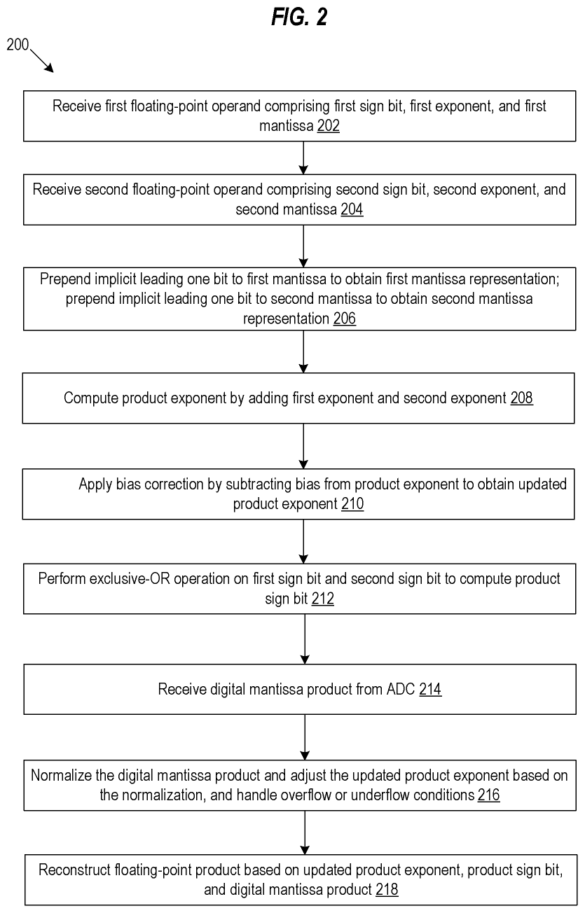

FIG. 2 is a flowchart 200 that illustrates a method for performing floating-point multiplication using a signed floating-point digital-to-analog converter, in accordance with an embodiment of the disclosure. FIG. 2 is explained in conjunction with elements from FIG. 1. With reference to FIG. 2, there is shown the flowchart 200. The operations of the exemplary method may be executed by the floating-point multiplier circuit 102 of FIG. 1, including the signed floating-point digital-to-analog converter (S-FP-DAC) 104, the pulse generation circuit 120, the integration circuit 122, the analog-to-digital converter (ADC) 124, and the digital processing circuit 126. The operations of the flowchart 200 may start at 202. For standalone multiplication operations, the shift register 110 capability may not be used, as shifting is primarily required when addition or accumulation is involved for exponent alignment purposes.

At 202, the operations include receiving a first floating-point operand comprising a first sign bit, a first exponent, and a first mantissa. In an embodiment of the disclosure, the S-FP-DAC 104 is configured to receive the first sign bit and the first mantissa of the first floating-point operand 128a. When an 8-bit FP8 number arrives (1 sign bit, 4 exponent bits, 3 mantissa bits), the first sign bit is routed to the sign bit storage 112 and the sign-controlled switches 114. The first exponent is stored separately for digital computation by the digital processing circuit 126. The first mantissa is provided to the mantissa storage 108 for storage and subsequent processing. The flowchart 200 then proceeds to 204.

At 204, the operations include receiving a second floating-point operand comprising a second sign bit, a second exponent, and a second mantissa. In an embodiment of the disclosure, the pulse generation circuit 120 is configured to receive the second mantissa of the second floating-point operand 128b. The second sign bit may be provided to the sign-controlled switches 114 when the second mantissa representation is an unsigned mantissa representation. The second exponent is stored separately for digital computation by the digital processing circuit 126. The second mantissa is provided to the pulse generation circuit 120 for generating the pulse signal 130 having a duration proportional to a second mantissa representation of the second mantissa, where one operand (1+mantissa) is stored in the S-FP-DAC 104 as current magnitude and the other operand controls pulse width. The flowchart 200 then proceeds to 206.

At 206, the operations include prepending an implicit leading one bit to the first mantissa to obtain a first mantissa representation and prepending an implicit leading one bit to the second mantissa to obtain a second mantissa representation. In an embodiment of the disclosure, the mantissa storage 108 is configured to store the first mantissa representation of the first mantissa. The first mantissa representation comprises the implicit leading one bit prepended to the first mantissa. For a 3-bit mantissa (M₂, M₁, M₀), the first mantissa representation is a 4-bit value represented as {1, M₂, M₁, M₀}, where the 4-bit value loads into the shift register 110 controlling the current sources. The pulse generation circuit 120 processes the second mantissa representation comprising the implicit leading one bit prepended to the second mantissa. The implicit leading one bit corresponds to the implicit leading one in IEEE floating-point representation that is not stored but assumed during computation. Numbers are normalized to the form 1.X×2^{E} where the leading 1 is implicit. The flowchart 200 then proceeds to 208.

At 208, the operations include computing a product exponent by adding the first exponent and the second exponent. In an embodiment of the disclosure, the digital processing circuit 126 is configured to compute the product exponent by adding the first exponent of the first floating-point operand 128a and the second exponent of the second floating-point operand 128b. The product exponent computation may be expressed as E_{C}=E_{A}+E_{B}. The exponent computation is performed entirely in the digital domain using simple addition operations and does not require intensive multiply operations. Operations on the exponent are simple addition and subtraction operations that may be implemented with digital gates without needing analog techniques. The flowchart 200 then proceeds to 210.

At 210, the operations include applying a bias correction to the product exponent to obtain an updated product exponent. In an embodiment of the disclosure, the digital processing circuit 126 is further configured to apply the bias correction to the product exponent to maintain IEEE 754 compliance. The bias correction may be expressed as EXP(Y)=E_{A}+E_{B}−B, where B represents the bias value. The bias value depends on the floating-point format being used. For FP16 format, the bias value is 15. For FP8 format with a 4-bit exponent, the bias value is 7. The bias splits the full range of exponent bits to half for positive values and half for negative values. The result of FP8×FP8 produces an exponent of 4+4=5 bits with possible overflow by 1 bit. The flowchart 200 then proceeds to 212.

At 212, the operations include performing an exclusive-OR operation on the first sign bit and the second sign bit to compute a product sign bit. In an embodiment of the disclosure, the digital processing circuit 126 is further configured to perform the exclusive-OR operation on the first sign bit S_{A} and the second sign bit S_{B} of the second floating-point operand 128b to compute the product sign bit S_{C}. The product sign bit computation may be expressed as S_{C}=S_{A}⊕S_{B}. When both sign bits are equal (both zero or both one), the product sign bit is zero, indicating a positive result. When the sign bits are different (one zero and one one), the product sign bit is one, indicating a negative result. The XOR of signs for multiplication determines the product sign, which is a key operation performed in the digital domain. The flowchart 200 then proceeds to 214.

At 214, the operations include receiving a digital mantissa product from the ADC 124. In an embodiment of the disclosure, the ADC 124 is configured to convert the voltage signal 132 to the digital mantissa product Y_{M}. The voltage signal 132 is produced by the integration circuit 122 as a result of accumulating a charge from the flow of the signed current output for the duration of the pulse signal 130. The integration circuit 122 accumulates the charge from the flow of the signed current output for the duration to produce the voltage signal 132 proportional to a product of the first mantissa representation and the second mantissa representation. The integration on the capacitor produces the product of mantissas through the relationship Vₒᵤₜ=I×T/C, where I represents the current magnitude determined by the first mantissa representation, T represents the pulse duration determined by the second mantissa representation, and C represents the capacitance value. The ADC 124 extracts extra bits to account for signed operations and overflow conditions. The sign may be determined from current or voltage polarity (positive or negative). The digital processing circuit 126 receives the digital mantissa product Y_{M} from the ADC 124. For FP8×FP8, the mantissa product is (1+3)×(1+3)=4× 4=8 bits, represented as 1+7 bits, requiring total internal precision of 13 bits (1 sign+5 exponent+7 mantissa). The flowchart 200 then proceeds to 216.

At 216, the operations include normalizing the digital mantissa product, adjusting the updated product exponent based on the normalization, and handling overflow or underflow conditions. In an embodiment of the disclosure, the digital processing circuit 126 is configured to normalize the digital mantissa product to align the result to a standard floating-point representation format. The mantissa computation follows the relationship M_{CC}=(1+M_{A})×(1+M_{B}), and the result M_{C} is extracted from M_{CC} after analog-to-digital conversion, represented as (1+M_{C}′). When the product mantissa exceeds the representable range, the digital processing circuit 126 shifts the digital mantissa product and adjusts the updated product exponent accordingly. If the output must be FP8, the most significant bits are retained and the least significant bits are discarded. The digital processing circuit 126 also handles overflow conditions when the updated product exponent exceeds the maximum representable exponent value and underflow conditions when the updated product exponent falls below the minimum representable exponent value. Overflow and underflow flags indicate when the result exceeds the representable range. The flowchart 200 then proceeds to 218.

At 218, the operations include reconstructing a floating-point product in an IEEE floating-point format based on the updated product exponent, the product sign bit, and the digital mantissa product. In an embodiment of the disclosure, the digital processing circuit 126 is further configured to reconstruct the floating-point product 134 of the first floating-point operand 128a and the second floating-point operand 128b in the IEEE floating-point format. The floating-point product 134 is denoted as Y=A×B. The digital processing circuit 126 combines the product sign bit S_{C}, the adjusted updated product exponent, and the normalized digital mantissa product to form the complete floating-point product 134 in the IEEE floating-point format. The floating-point product 134 may be output in FP8 format, FP16 format, BF16 format, or other floating-point formats depending on the configuration of the floating-point multiplier circuit 102.

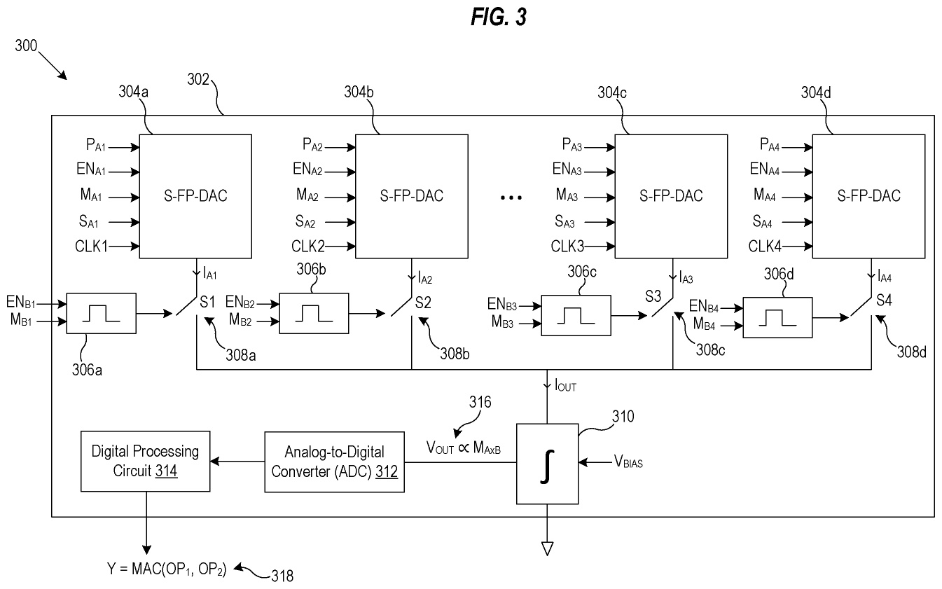

FIG. 3 is a diagram 300 that illustrates a floating-point multiply-accumulate (MAC) circuit 302 configured to perform multiply-accumulate operations on floating-point operands, in accordance with an embodiment of the disclosure. FIG. 3 is explained in conjunction with elements from FIG. 1 and FIG. 2. The floating-point MAC circuit 302 comprises a plurality of S-FP-DACs including a first S-FP-DAC 304a, a second S-FP-DAC 304b, a third S-FP-DAC 304c, and a fourth S-FP-DAC 304d arranged in parallel. The floating-point MAC circuit 302 further comprises a plurality of pulse switches including a first pulse switch 308a, a second pulse switch 308b, a third pulse switch 308c, and a fourth pulse switch 308d. The floating-point MAC circuit 302 further comprises a plurality of pulse generation circuits including a first pulse generation circuit 306a, a second pulse generation circuit 306b, a third pulse generation circuit 306c, and a fourth pulse generation circuit 306d. The floating-point MAC circuit 302 further comprises an integration circuit 310 coupled to the plurality of pulse switches, an analog-to-digital converter (ADC) 312 configured to convert a voltage signal to a digital accumulated mantissa product, and a digital processing circuit 314. The ellipsis between the second S-FP-DAC 304b and the third S-FP-DAC 304c indicates that additional S-FP-DACs may be included in the floating-point MAC circuit 302 to support larger multiply-accumulate operations. In various embodiments, the floating-point MAC circuit 302 may include 4, 8, 16, 32, 64, or more S-FP-DACs arranged in parallel to support different vector sizes and computational throughput requirements. The floating-point MAC circuit 302 is configured to compute a MAC output 318 represented as Y=MAC(OP1, OP2), where OP1 represents a first operand set and OP2 represents a second operand set. The floating-point MAC circuit 302 may be configured to compute Y=x₁×w₁+x₂×w₂+x₃×w₃+ . . . +x_{N}×w_{N}, where each xᵢ and wᵢ is in a floating-point format such as FP8, FP16, or BF16.

Each S-FP-DAC of the plurality of S-FP-DACs is configured to receive a respective first sign bit and a respective first mantissa of a respective first floating-point operand of the first operand set, and produce a respective signed current output based on the respective first sign bit and the respective first mantissa. The first S-FP-DAC 304a receives inputs P_{A1} (a control signal for addition or subtraction operations), EN_{A1} (an enable signal for selective activation), M_{A1} (a mantissa input), S_{A1} (a sign bit input), and CLK₁ (a clock signal for shift register operations), and produces a current output I_{A1} (a signed current output representing the mantissa value). The second S-FP-DAC 304b receives inputs P_{A2}, EN_{A2}, M_{A2}, S_{A2}, and CLK₂, and produces a current output I_{A2}. The third S-FP-DAC 304c receives inputs P_{A3}, EN_{A3}, M_{A3}, S_{A3}, and CLK₃, and produces a current output I_{A3}. The fourth S-FP-DAC 304d receives inputs P_{A4}, EN_{A4}, M_{A4}, S_{A4}, and CLK₄, and produces a current output I_{A4}. Each S-FP-DAC of the plurality of S-FP-DACs comprises a positive current source bank and a negative current source bank, as described with reference to the signed floating-point digital-to-analog converter 104 of FIG. 1. The positive current source bank comprises a first plurality of binary-weighted current sources and the negative current source bank comprises a second plurality of binary-weighted current sources. For a 3-bit mantissa (M₂, M₁, M₀) as used in FP8 format, the current sources may be configured with an always-on MSB current source of 8×I₀ (where I₀ represents a unit current value) representing the implicit leading one, M₂ controlling 4×I₀, M₁ controlling 2×I₀, and M₀ controlling 1×I₀, where the total output current represents (1+mantissa)×I₀. Each S-FP-DAC of the plurality of S-FP-DACs further comprises a mantissa storage configured to store a respective first mantissa representation of the respective first mantissa, wherein bits of the respective first mantissa representation selectively enable corresponding current sources in the positive current source bank and the negative current source bank to produce a positive current output and a negative current output, respectively. The respective first mantissa representation comprises an implicit leading one bit prepended to bits of the respective first mantissa. Each S-FP-DAC of the plurality of S-FP-DACs further comprises sign-controlled switches configured to route the positive current output or the negative current output to the output of the respective S-FP-DAC based on the respective first sign bit to produce the respective signed current output. The sign bit equal to one closes the switch to the negative current source bank, and the sign bit equal to zero closes the switch to the positive current source bank, effectively flipping current direction for negative numbers. The mantissa may be represented as signed one's complement in the S-FP-DAC.

The mantissa storage of each S-FP-DAC comprises a shift register configured to perform right-shift operations on the bits of the respective first mantissa representation based on clock signals. The right-shift operations shift a zero bit into a most significant bit position of the respective first mantissa representation for each clock cycle of the clock signals. Each mantissa bit position has an associated shift register cell, and bits are stored as [1 (always on for implicit leading one), W₁, W₀] for a 3-bit mantissa example, where W₁ and W₀ represent mantissa bit values stored in the shift register cells. On each clock cycle, bits shift from left to right (MSB toward LSB), with X₀=0 (a zero value shifted into the most significant bit position) shifted in from the MSB side, and LSB bits are shifted out and discarded. The number of clock cycles determines the shift amount, which equals the exponent difference. By removing the clock signal and holding it static, the shifting of bits stops. As right shift occurs, LSBs are discarded, resulting in lower precision representation of the same number. The shift register enables exponent alignment for multiply-accumulate operations by shifting the respective first mantissa representation to account for exponent differences between operands. For MAC operations, shifting may be performed before multiplication begins, not after, because the addition requires aligned exponents, and it may be equivalent in terms of precision loss whether shifting occurs before or after multiplication. The digital processing circuit 314 is configured to apply a number of clock cycles of the clock signals to each S-FP-DAC of the plurality of S-FP-DACs, wherein the number of clock cycles equals the difference between a maximum exponent and a respective product exponent for the respective S-FP-DAC. For example, if the first S-FP-DAC 304a has a product exponent that is 2 less than the maximum exponent, the digital processing circuit 314 applies 2 clock cycles to CLK₁ to shift the mantissa of the first S-FP-DAC 304a by 2 bit positions before multiplication begins.

As further shown in FIG. 3, each pulse switch of the plurality of pulse switches is coupled to an output of a respective S-FP-DAC of the plurality of S-FP-DACs. The first pulse switch 308a is coupled to the output of the first S-FP-DAC 304a. The second pulse switch 308b is coupled to the output of the second S-FP-DAC 304b. The third pulse switch 308c is coupled to the output of the third S-FP-DAC 304c. The fourth pulse switch 308d is coupled to the output of the fourth S-FP-DAC 304d. Each pulse generation circuit of the plurality of pulse generation circuits is configured to generate a respective pulse signal based on a respective second mantissa of a respective second floating-point operand of the second operand set. The first pulse generation circuit 306a receives inputs EN_{B1} (an enable signal for the second operand) and M_{B1} (a mantissa value of the second operand) and generates a pulse signal S₁ (a timing control signal) to control the first pulse switch 308a. The second pulse generation circuit 306b receives inputs EN_{B2} and M_{B2} and generates a pulse signal S₂ to control the second pulse switch 308b. The third pulse generation circuit 306c receives inputs EN_{B3} and M_{B3} and generates a pulse signal S₃ to control the third pulse switch 308c. The fourth pulse generation circuit 306d receives inputs EN_{B4} and M_{B4} and generates a pulse signal S₄ to control the fourth pulse switch 308d. The respective pulse signal is generated with a respective pulse duration proportional to a respective second mantissa representation of the respective second mantissa, expressed as M_{B}′×Tᵤ, where Tᵤ represents a unit time value and M_{B}′=2^{B}+M_{B} represents the second mantissa representation with the implicit leading one bit. The respective second mantissa representation is an unsigned value and comprises an implicit leading one bit prepended to bits of the respective second mantissa. Each respective pulse signal enables a respective pulse switch of the plurality of pulse switches to allow a flow of the respective signed current output for a respective duration. The mantissa computation follows the relationship M_{CC}=(1+M_{A})×(1+M_{B}), where M_{CC} represents the computed mantissa product, M_{A} represents the first mantissa, M_{B} represents the second mantissa, the first term (1+M_{A}) is stored in the S-FP-DAC as current magnitude and the second term (1+M_{B}) represents the pulse signal duration.

The outputs of the pulse switches are connected to a common node that feeds into the integration circuit 310. The integration circuit 310 comprises a capacitor coupled to a bias voltage V_{BIAS} (a reference voltage for the integration operation). The integration circuit 310 is coupled to the plurality of pulse switches and accumulates charges from the flow of the respective signed current output of each S-FP-DAC of the plurality of S-FP-DACs for the respective duration to produce a voltage signal 316 proportional to an accumulated product of pairwise mantissas of the first operand set and the second operand set. The voltage signal 316 is labeled as V_{OUT} (an output voltage representing the accumulated result) and is proportional to the product of mantissas M_{A}×B. The voltage signal 316 is across the capacitor as a sum of charges accumulated from the flow of the respective signed current output of each S-FP-DAC of the plurality of S-FP-DACs for the respective duration. The integration circuit 310 produces an output current I_{OUT} (a combined current from all enabled S-FP-DACs) that represents the accumulated current from all enabled S-FP-DACs. The mathematical relationship for the accumulated voltage may be expressed as Vₒᵤₜ=ΣIᵢ×Tᵢ/C, where Iᵢ represents the current magnitude from the i-th S-FP-DAC, Tᵢ represents the pulse duration from the i-th pulse generation circuit, C represents the capacitance value, and N represents the number of enabled S-FP-DACs. The capacitor of the integration circuit 310 is connected to a ground terminal to complete the integration path. All enabled elements may perform multiplication simultaneously, with currents summing on the shared integration capacitor.

With continued reference to FIG. 3, the analog-to-digital converter (ADC) 312 receives the voltage signal 316 and is configured to convert the voltage signal 316 to a digital accumulated mantissa product representing the result of the multiply-accumulate operation in digital form. The ADC 312 extracts extra bits to account for signed operations and overflow conditions. The sign may be determined from current or voltage polarity (positive or negative). The output of the analog-to-digital converter 312 is provided to the digital processing circuit 314. The digital processing circuit 314 processes the digital accumulated mantissa product to produce a MAC output 318 represented as Y=MAC(OP1, OP2), where Y represents the final multiply-accumulate result, OP1 represents the first operand set and OP2 represents the second operand set. The digital processing circuit 314 is configured to compute each product exponent of a plurality of respective product exponents for a pair of the respective first floating-point operand and the respective second floating-point operand by adding a respective first exponent of the respective first floating-point operand and a respective second exponent of the respective second floating-point operand, expressed as ECᵢ=EXP(xᵢ)+EXP(wᵢ), where ECᵢ represents the computed product exponent for the i-th operand pair, EXP(xᵢ) represents the exponent of the i-th first operand, and EXP(wᵢ) represents the exponent of the i-th second operand. This exponent computation is done entirely in the digital domain before any analog computation. The digital processing circuit 314 is further configured to determine a maximum exponent among the plurality of respective product exponents, expressed as MaxEXP=max(EXP(Y₁), EXP(Y₂), . . . , EXP(Y_{N})), where MaxEXP represents the maximum product exponent and EXP(Yᵢ) represents the product exponent for the i-th multiplication result. The digital processing circuit 314 is further configured to generate the clock signals for each S-FP-DAC of the plurality of S-FP-DACs based on a difference between the maximum exponent and a respective product exponent of the plurality of respective product exponents, where the shift amount equals MaxEXP−ECᵢ for each element.

Each S-FP-DAC of the plurality of S-FP-DACs further comprises an enable switch configured to selectively connect or disconnect the respective signed current output from the integration circuit 310 based on a respective enable signal. The enable switch provides selective activation of S-FP-DAC elements based on exponent grouping during MAC operations. When the respective enable signal equals zero, the respective S-FP-DAC does not participate in the operation and does not output any current. When the respective enable signal equals one, the respective S-FP-DAC participates in the operation and outputs current to the integration circuit 310. The digital processing circuit 314 is further configured to group the plurality of S-FP-DACs into a plurality of groups based on the plurality of respective product exponents. Each group of the plurality of groups comprises a subset of S-FP-DACs of the plurality of S-FP-DACs, and the subset of S-FP-DACs have respective product exponents within a predetermined range. The digital processing circuit 314 is further configured to generate the respective enable signal for each S-FP-DAC of the plurality of S-FP-DACs to enable the subset of S-FP-DACs and disable S-FP-DACs of the plurality of S-FP-DACs different from the subset of S-FP-DACs. For example, for FP8 format with a 3-bit mantissa (plus 1 implicit bit equals 4 bits total), the maximum useful shift is 3 bits (shift by 4 makes value equal to zero), and products with exponent differences greater than 3 may not be accumulated together in the same group. For a 64-element MAC with input exponents ranging from −15 to +15, product exponents may range from −30 to +30 (total 61 values), and with 3-bit shift capability, approximately 20 groups may be needed, with groups such as [−30 to −27], [−26 to −24], [−23 to −21], and so forth up to [+27 to +30]. The digital processing circuit 314 groups products into ranges of consecutive exponents and processes each group sequentially, storing intermediate results in the digital domain and combining all partial sums using standard floating-point addition rules after all groups have been processed. Two approaches may be used for group processing: a fixed rule approach that processes all groups sequentially regardless of data distribution, guaranteeing completion in a fixed number of steps, or an adaptive approach that tracks which elements fall into which groups using a counter and skips empty groups, potentially completing in fewer steps.

The digital processing circuit 314 is further configured to perform an exclusive-OR operation on the respective first sign bit and a respective second sign bit of the respective second floating-point operand to compute a respective product sign bit for the respective first floating-point operand and the respective second floating-point operand, expressed as S(Yᵢ)=S(xᵢ)⊕S(wᵢ), where S(Yᵢ) represents the sign bit of the i-th product, S(xᵢ) represents the sign bit of the i-th first operand, and S(wᵢ) represents the sign bit of the i-th second operand. The digital processing circuit 314 is further configured to generate a respective control signal for each S-FP-DAC of the plurality of S-FP-DACs based on the respective product sign bit. The sign-controlled switches of each S-FP-DAC are configured to selectively invert routing of the positive current output and the negative current output based on the respective control signal. The control signal P (a signal for controlling addition or subtraction operations) enables support for subtraction operations by selectively inverting the sign bit, effectively computing accumulation with subtraction by computing a sum with a negated operand. When P equals 1, NOT(S_{A}) represents subtraction, and when P equals 0, S_{A} represents addition. Operations in the digital domain may include exponent addition and subtraction, exponent comparison to find the maximum, shift amount calculation, enable signal generation, grouping decisions, and final sum of partial results. Operations in the analog domain may include mantissa multiplication using the IT-DAC method and mantissa accumulation through current summation on the shared integration capacitor. Mixed domain operations may include sign handling with digital control of analog current direction and mantissa shifting with digital clock control of analog current sources. In various embodiments, the floating-point MAC circuit 302 may be deployed in neural network accelerators for inference and training applications, digital signal processing systems, scientific computing systems, and other applications where high-throughput floating-point multiply-accumulate operations are required.

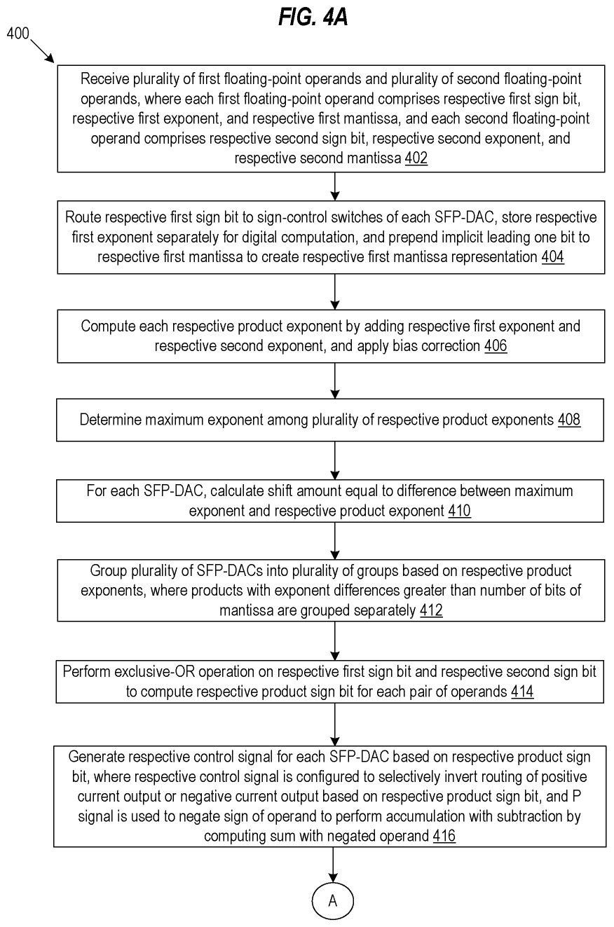

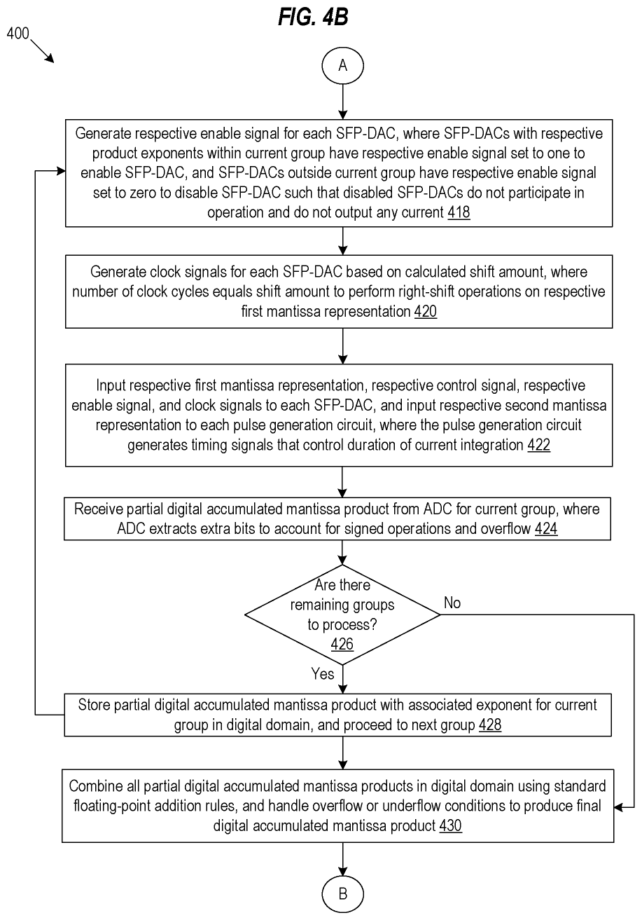

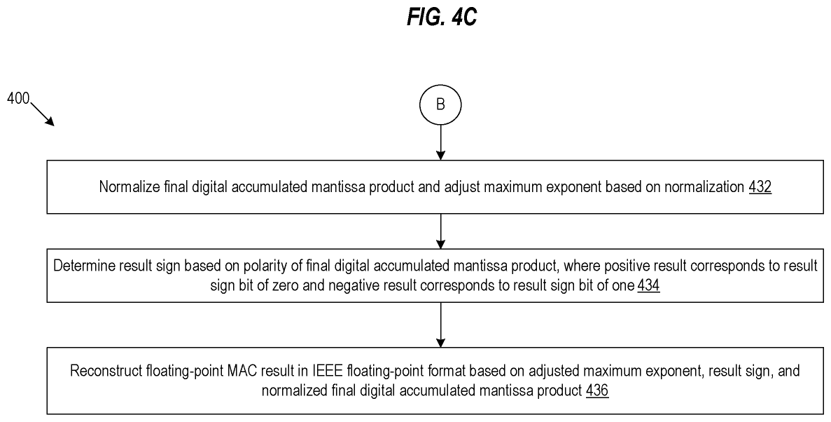

FIGS. 4A, 4B, and 4C collectively illustrate a flowchart 400 for a method of performing floating-point multiply-accumulate operations using signed floating-point digital-to-analog converters, in accordance with an embodiment of the disclosure. FIGS. 4A, 4B, and 4C are explained in conjunction with elements from FIG. 1, FIG. 2, and FIG. 3. With reference to FIGS. 4A, 4B, and 4C, there is shown the flowchart 400. The operations of the exemplary method may be executed by the floating-point MAC circuit 302 of FIG. 3, including the plurality of S-FP-DACs (the first S-FP-DAC 304a, the second S-FP-DAC 304b, the third S-FP-DAC 304c, and the fourth S-FP-DAC 304d), the plurality of pulse generation circuits (the first pulse generation circuit 306a, the second pulse generation circuit 306b, the third pulse generation circuit 306c, and the fourth pulse generation circuit 306d), the integration circuit 310, the analog-to-digital converter 312, and the digital processing circuit 314. The operations of the flowchart 400 may start at 402.

At 402, the operations include receiving a plurality of first floating-point operands of a first operand set and a plurality of second floating-point operands of a second operand set. Each first floating-point operand of the first operand set comprises a respective first sign bit, a respective first exponent, and a respective first mantissa. Each second floating-point operand of the second operand set comprises a respective second sign bit, a respective second exponent, and a respective second mantissa. In an embodiment of the disclosure, each S-FP-DAC of the plurality of S-FP-DACs is configured to receive the respective first sign bit and the respective first mantissa of a respective first floating-point operand of the first operand set. Each pulse generation circuit of the plurality of pulse generation circuits is configured to receive the respective second mantissa of a respective second floating-point operand of the second operand set. The digital processing circuit 314 receives the respective first exponent and the respective second exponent for each pair of operands for digital computation. The flowchart 400 then proceeds to 404.

At 404, the operations include routing the respective first sign bit to sign-controlled switches of each S-FP-DAC, storing the respective first exponent separately for digital computation, and prepending an implicit leading one bit to the respective first mantissa to create a respective first mantissa representation. In an embodiment of the disclosure, when floating-point numbers arrive at each S-FP-DAC, the respective first sign bit is routed to the sign-controlled switches 114 of each S-FP-DAC for controlling the routing of the positive current output or the negative current output. The respective first exponent is stored separately in the digital processing circuit 314 for digital computation of product exponents and shift amounts. The respective first mantissa has an implicit leading one bit prepended to bits of the respective first mantissa to create the respective first mantissa representation. The respective first mantissa representation is stored in the mantissa storage 108 of each S-FP-DAC. For a 3-bit mantissa (M₂, M₁, M₀) as used in FP8 format, the respective first mantissa representation is a 4-bit value represented as {1, M₂, M₁, M₀

At 406, the operations include computing each respective product exponent of a plurality of respective product exponents by adding the respective first exponent and the respective second exponent for a pair of the respective first floating-point operand and the respective second floating-point operand. In an embodiment of the disclosure, the digital processing circuit 314 is configured to compute each product exponent of the plurality of respective product exponents for the pair of the respective first floating-point operand and the respective second floating-point operand by adding the respective first exponent of the respective first floating-point operand and the respective second exponent of the respective second floating-point operand. The product exponent computation may be expressed as ECᵢ=EXP(xᵢ)+EXP(wᵢ). EXP(xᵢ) represents the respective first exponent and EXP(wᵢ) represents the respective second exponent. The digital processing circuit 314 applies bias correction to each respective product exponent to maintain IEEE 754 compliance. The bias correction may be expressed as ECᵢ=EXP(xᵢ)+EXP(wᵢ)−B, where B represents the bias value. The exponent computation is performed entirely in the digital domain before any analog computation and does not require intensive multiply operations. The flowchart 400 then proceeds to 408.

At 408, the operations include determining a maximum exponent among the plurality of respective product exponents. In an embodiment of the disclosure, the digital processing circuit 314 is configured to determine the maximum exponent among the plurality of respective product exponents. The maximum exponent determination may be expressed as MaxEXP=max(EXP(Y₁), EXP(Y₂), EXP(Y₃), . . . , EXP(Y_{N})). EXP(Yᵢ) represents the respective product exponent for the i-th pair of operands and N represents the total number of operand pairs. The maximum exponent serves as the reference exponent to which all other operands are aligned for accumulation. The flowchart 400 then proceeds to 410.

At 410, the operations include calculating a difference between the maximum exponent and the respective product exponent for each S-FP-DAC of the plurality of S-FP-DACs. In an embodiment of the disclosure, the digital processing circuit 314 is configured to calculate the difference between the maximum exponent and the respective product exponent of the plurality of respective product exponents for each S-FP-DAC. The difference calculation may be expressed as shift amount=MaxEXP−ECᵢ. MaxEXP represents the maximum exponent and ECᵢ represents the respective product exponent for the i-th S-FP-DAC. The difference determines a number of clock cycles to be applied to the shift register 110 of each S-FP-DAC to align the respective first mantissa representation to the maximum exponent before multiplication begins. For MAC operations, shifting may be performed before multiplication begins, not after, because the addition requires aligned exponents. The flowchart 400 then proceeds to 412.

At 412, the operations include grouping the plurality of S-FP-DACs into a plurality of groups based on the plurality of respective product exponents. Each group of the plurality of groups comprises a subset of S-FP-DACs of the plurality of S-FP-DACs. The subset of S-FP-DACs have respective product exponents within a predetermined range. In an embodiment of the disclosure, the digital processing circuit 314 is configured to group the plurality of S-FP-DACs into the plurality of groups based on the plurality of respective product exponents. For FP8 format with a 3-bit mantissa (plus 1 implicit bit equals 4 bits total), the maximum useful shift is 3 bits, as shift by 4 makes the value equal to zero. Products with exponent differences greater than 3 may not be accumulated together in the same group. For a 64-element MAC with input exponents ranging from −15 to +15, product exponents may range from −30 to +30 (total 61 values), and with 3-bit shift capability, approximately 20 groups may be needed. The groups may be organized as consecutive exponent ranges such as [−30 to −27], [−26 to −24], [−23 to −21], and so forth up to [+27 to +30]. The flowchart 400 then proceeds to 414.

At 414, the operations include performing an exclusive-OR operation on the respective first sign bit and a respective second sign bit of the respective second floating-point operand to compute a respective product sign bit for the respective first floating-point operand and the respective second floating-point operand. In an embodiment of the disclosure, the digital processing circuit 314 is configured to perform the exclusive-OR operation on the respective first sign bit S(xᵢ) and the respective second sign bit S(wᵢ) of the respective second floating-point operand to compute the respective product sign bit S(Yᵢ) for the respective first floating-point operand and the respective second floating-point operand. The respective product sign bit computation may be expressed as S(Yᵢ)=S(xᵢ)⊕S(wᵢ). When both sign bits are equal (both zero or both one), the respective product sign bit is zero, indicating a positive result. When the sign bits are different (one zero and one one), the respective product sign bit is one, indicating a negative result. The flowchart 400 then proceeds to 416.

At 416, the operations include generating a respective control signal for each S-FP-DAC of the plurality of S-FP-DACs based on the respective product sign bit. The sign-controlled switches of each S-FP-DAC are configured to selectively invert routing of the positive current output and the negative current output based on the respective control signal. In an embodiment of the disclosure, the digital processing circuit 314 is configured to generate the respective control signal for each S-FP-DAC of the plurality of S-FP-DACs based on the respective product sign bit. The control signal P enables support for subtraction operations by selectively inverting the sign bit. When P equals 1, NOT(S_{A}) represents subtraction, effectively computing accumulation with subtraction by computing a sum with a negated operand. When P equals 0, S_{A} represents addition. The P signal may be used to negate the sign of an operand to perform A+(−B) instead of A+B. The flowchart 400 then proceeds to 418.

At 418, the operations include generating a respective enable signal for each S-FP-DAC of the plurality of S-FP-DACs to enable the subset of S-FP-DACs and disable S-FP-DACs of the plurality of S-FP-DACs different from the subset of S-FP-DACs. In an embodiment of the disclosure, the digital processing circuit 314 is configured to generate the respective enable signal for each S-FP-DAC of the plurality of S-FP-DACs based on whether the respective product exponent falls within a current group being processed. S-FP-DACs with respective product exponents within the current group, which constitutes the subset of S-FP-DACs, have their respective enable signal set to one to enable the S-FP-DAC. This allows the S-FP-DAC to participate in the current accumulation operation and output current to the integration circuit 310. S-FP-DACs outside the current group, which are S-FP-DACs of the plurality of S-FP-DACs different from the subset of S-FP-DACs, have their respective enable signal set to zero to disable the S-FP-DAC. Disabled S-FP-DACs do not participate in the operation and do not output any current. As described in FIG. 3, each S-FP-DAC of the plurality of S-FP-DACs further comprises an enable switch configured to selectively connect or disconnect the respective signed current output from the integration circuit 310 based on the respective enable signal. This selective activation enables the floating-point MAC circuit 302 to process operands with similar exponents together while excluding operands with exponents outside the current group's range. The flowchart 400 then proceeds to 420.

At 420, the operations include generating clock signals for each S-FP-DAC of the plurality of S-FP-DACs based on the difference between the maximum exponent and the respective product exponent of the plurality of respective product exponents. In an embodiment of the disclosure, the digital processing circuit 314 is configured to generate the clock signals for each S-FP-DAC of the plurality of S-FP-DACs based on the difference between the maximum exponent and the respective product exponent. The digital processing circuit 314 is further configured to apply a number of clock cycles of the clock signals to each S-FP-DAC of the plurality of S-FP-DACs. The number of clock cycles equals the difference between the maximum exponent and the respective product exponent for the respective S-FP-DAC. For each S-FP-DAC, the mantissa storage comprises a shift register configured to perform right-shift operations on the bits of the respective first mantissa representation based on the clock signals. The right-shift operations shift a zero bit into a most significant bit position of the respective first mantissa representation for each clock cycle of the clock signals. For example, if the first S-FP-DAC 304a has a respective product exponent that is 2 less than the maximum exponent, the digital processing circuit 314 applies 2 clock cycles to CLK₁ to shift the respective first mantissa representation of the first S-FP-DAC 304a by 2 bit positions. After shifting, all respective first mantissa representations of the enabled S-FP-DACs are aligned to the same effective exponent before multiplication begins. The flowchart 400 then proceeds to 422.

At 422, the operations include inputting the respective first mantissa representation, respective control signal, respective enable signal, and clock signals to each S-FP-DAC, and inputting a respective second mantissa representation to each pulse generation circuit. In an embodiment of the disclosure, each S-FP-DAC of the plurality of S-FP-DACs receives the respective first mantissa representation stored in the mantissa storage, the respective control signal based on the respective product sign bit, the respective enable signal indicating whether the S-FP-DAC participates in the current group's computation, and the clock signals for performing right-shift operations. As described in FIG. 3, the first S-FP-DAC 304a receives inputs P_{A1}, EN_{A1}, M_{A1}, S_{A1}, and CLK₁. The second S-FP-DAC 304b receives inputs P_{A2}, EN_{A2}, M_{A2}, S_{A2}, and CLK₂. The third S-FP-DAC 304c receives inputs P_{A3}, EN_{A3}, M_{A3}, S_{A3}, and CLK₃. The fourth S-FP-DAC 304d receives inputs P_{A4}, EN_{A4}, M_{A4}, S_{A4}, and CLK₄. Each pulse generation circuit of the plurality of pulse generation circuits is configured to generate a respective pulse signal based on a respective second mantissa of a respective second floating-point operand of the second operand set. The respective pulse signal is generated with a respective pulse duration proportional to a respective second mantissa representation of the respective second mantissa. The respective second mantissa representation is an unsigned value and comprises an implicit leading one bit prepended to bits of the respective second mantissa. As described in FIG. 3, the first pulse generation circuit 306a receives inputs EN_{B1} and M_{B1}. The second pulse generation circuit 306b receives inputs EN_{B2} and M_{B2}. The third pulse generation circuit 306c receives inputs EN_{B3} and M_{B3}. The fourth pulse generation circuit 306d receives inputs EN_{B4} and M_{B4}. Each respective pulse signal enables a respective pulse switch of the plurality of pulse switches to allow a flow of the respective signed current output for a respective duration. All enabled S-FP-DACs perform multiplication simultaneously, with currents summing on the shared integration capacitor of the integration circuit 310. The flowchart 400 then proceeds to 424.

At 424, the operations include receiving a partial digital accumulated mantissa product from the ADC for the current group. In an embodiment of the disclosure, the integration circuit 310 is coupled to the plurality of pulse switches and accumulates charges from the flow of the respective signed current output of each S-FP-DAC of the plurality of S-FP-DACs for the respective duration to produce a voltage signal proportional to an accumulated product of pairwise mantissas of the first operand set and the second operand set. The voltage signal 316 represents the accumulated product of pairwise mantissas for the S-FP-DACs within the current group. The analog-to-digital converter 312 is configured to convert the voltage signal to a digital accumulated mantissa product. The analog-to-digital converter 312 receives the voltage signal 316 and converts the voltage signal 316 to a partial digital accumulated mantissa product representing the result of the multiply-accumulate operation for the current group in digital form. The analog-to-digital converter 312 extracts extra bits to account for signed operations and overflow conditions. The digital processing circuit 314 receives the partial digital accumulated mantissa product from the analog-to-digital converter 312. The partial digital accumulated mantissa product represents the sum of products for operand pairs whose respective product exponents fall within the current group's exponent range. The flowchart 400 then proceeds to 426.

At 426, the operations include determining whether there are remaining groups of the plurality of groups to process. In an embodiment of the disclosure, the digital processing circuit 314 is configured to determine whether all groups of the plurality of groups have been processed. The digital processing circuit 314 tracks which groups have been processed and which groups remain to be processed. If there are remaining groups to process (Yes branch), the flowchart 400 proceeds to 428. If there are no remaining groups to process (No branch), the flowchart 400 proceeds to 430. Two approaches may be used for group processing: a fixed rule approach that processes all groups sequentially regardless of data distribution, guaranteeing completion in a fixed number of steps, or an adaptive approach that tracks which elements fall into which groups using a counter and skips empty groups, potentially completing in fewer steps.

At 428, the operations include storing the partial digital accumulated mantissa product with an associated exponent for the current group in the digital domain, and returning to process the next group. In an embodiment of the disclosure, the digital processing circuit 314 is configured to store the partial digital accumulated mantissa product in a digital storage element along with the associated exponent for the current group. The associated exponent corresponds to the maximum exponent among the respective product exponents within the current group. The digital processing circuit 314 stores intermediate results in the digital domain for subsequent combination with partial results from other groups. After storing the partial digital accumulated mantissa product, the flowchart 400 returns to earlier steps to process the next group. The digital processing circuit 314 updates the current group to the next group in the sequence, generates new respective enable signals to enable the subset of S-FP-DACs within the next group and disable S-FP-DACs of the plurality of S-FP-DACs different from the subset of S-FP-DACs, and repeats the processing steps for the next group. The flowchart 400 continues iterating through the plurality of groups until all groups have been processed.

At 430, the operations include combining all partial digital accumulated mantissa products in the digital domain using standard floating-point addition rules and handling overflow or underflow conditions to produce a final digital accumulated mantissa product. In an embodiment of the disclosure, the digital processing circuit 314 is configured to combine all partial digital accumulated mantissa products stored during the processing of each group of the plurality of groups. The digital processing circuit 314 applies standard floating-point addition rules to combine the partial results, accounting for the different associated exponents of each partial digital accumulated mantissa product. The combination involves aligning the partial digital accumulated mantissa products to a common exponent by shifting mantissa values based on exponent differences, and then summing the aligned values. The digital processing circuit 314 handles overflow conditions when the combined result exceeds the maximum representable exponent value and underflow conditions when the combined result falls below the minimum representable exponent value. The digital processing circuit 314 produces a final digital accumulated mantissa product that represents the complete multiply-accumulate result across all operand pairs. The flowchart 400 then proceeds to 432.

At 432, the operations include normalizing the final digital accumulated mantissa product and adjusting the maximum exponent based on the normalization. In an embodiment of the disclosure, the digital processing circuit 314 is configured to normalize the final digital accumulated mantissa product to align the accumulated mantissa to a standard floating-point representation format. The normalization process shifts the final digital accumulated mantissa product such that the most significant non-zero bit occupies the position corresponding to the implicit leading one bit in IEEE floating-point representation. When the final digital accumulated mantissa product has leading zero bits, the digital processing circuit 314 left-shifts the final digital accumulated mantissa product and decrements the maximum exponent by the number of shift positions. When the final digital accumulated mantissa product has overflow bits beyond the implicit leading one position, the digital processing circuit 314 right-shifts the final digital accumulated mantissa product and increments the maximum exponent by the number of shift positions. The digital processing circuit 314 produces an adjusted maximum exponent that reflects the normalization applied to the final digital accumulated mantissa product. The flowchart 400 then proceeds to 434.

At 434, the operations include determining a result sign based on a polarity of the final digital accumulated mantissa product. In an embodiment of the disclosure, the digital processing circuit 314 is configured to determine the result sign based on whether the final digital accumulated mantissa product represents a positive value or a negative value. A positive result corresponds to a result sign bit of zero, indicating that the floating-point MAC result is a positive number. A negative result corresponds to a result sign bit of one, indicating that the floating-point MAC result is a negative number. The polarity of the final digital accumulated mantissa product may be determined from the sign of the voltage signal 316 produced by the integration circuit 310. As described in FIG. 3, the integration circuit comprises a capacitor and the voltage signal is across the capacitor as a sum of charges accumulated from the flow of the respective signed current output of each S-FP-DAC of the plurality of S-FP-DACs for the respective duration. A positive voltage corresponds to a positive accumulated value, and a negative voltage corresponds to a negative accumulated value. The analog-to-digital converter 312 may provide sign information along with the magnitude of the final digital accumulated mantissa product, or the digital processing circuit 314 may track the sign through the accumulation process based on the respective product sign bits computed for each operand pair. The flowchart 400 then proceeds to 436.

At 436, the operations include reconstructing a floating-point MAC result in an IEEE floating-point format based on the adjusted maximum exponent, the result sign, and the normalized final digital accumulated mantissa product. In an embodiment of the disclosure, the digital processing circuit 314 is configured to reconstruct the floating-point MAC result by combining the result sign bit, the adjusted maximum exponent, and the normalized final digital accumulated mantissa product into a complete floating-point representation. The digital processing circuit 314 formats the result sign bit as the most significant bit of the floating-point MAC result. The digital processing circuit 314 formats the adjusted maximum exponent in the exponent field of the floating-point MAC result, applying bias encoding as specified by the IEEE floating-point format.

The digital processing circuit 314 formats the normalized final digital accumulated mantissa product in the mantissa field of the floating-point MAC result, discarding the implicit leading one bit that is assumed but not stored in IEEE floating-point representation. The floating-point MAC result may be output as the MAC output 318 in FP8 format, FP16 format, BF16 format, or other floating-point formats depending on the configuration of the floating-point MAC circuit 302.

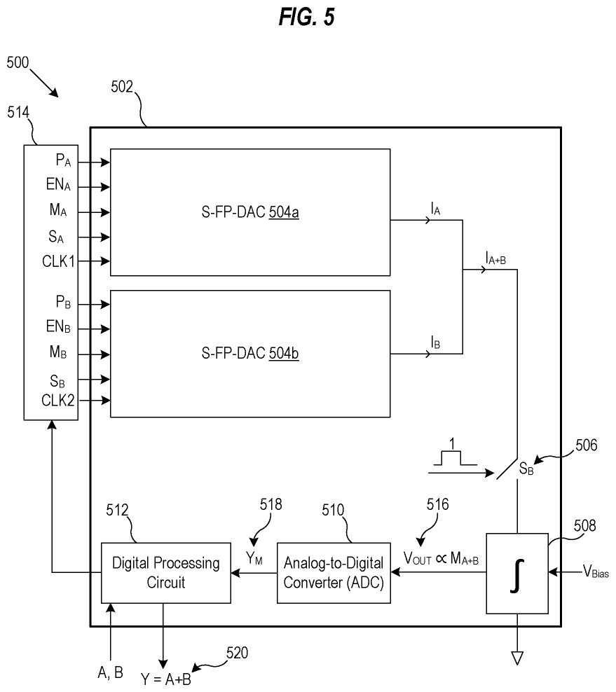

FIG. 5 is a diagram 500 that illustrates a floating-point adder circuit 502 configured to perform floating-point addition operations using signed floating-point digital-to-analog converters, in accordance with an embodiment of the disclosure. FIG. 5 is explained in conjunction with elements from FIG. 1, FIG. 2, FIG. 3, FIG. 4A, FIG. 4B, and FIG. 4C. The floating-point adder circuit 502 comprises a first S-FP-DAC 504a, a second S-FP-DAC 504b, a pulse switch 506, an integration circuit 508, an analog-to-digital converter 510, and a digital processing circuit 512. The floating-point adder circuit 502 is configured to receive an input signal set 514 comprising inputs for both the first S-FP-DAC 504a and the second S-FP-DAC 504b, and produce an accumulated output 520 representing the addition result. In various embodiments, the floating-point adder circuit 502 may be implemented as a standalone addition unit, as part of a larger compute-in-memory (CIM) architecture, or integrated within a neural network accelerator. The floating-point adder circuit 502 enables addition of two floating-point operands by combining signed current outputs from the first S-FP-DAC 504a and the second S-FP-DAC 504b, integrating the combined current, and converting the resulting voltage to a digital representation of the accumulated mantissa.

With continued reference to FIG. 5, the first S-FP-DAC 504a is configured to receive a first control signal PA, a first enable signal ENA, a first mantissa representation M_{A}, a first sign bit S_{A}, and a first clock signal CLK₁. The first S-FP-DAC 504a produces a first current output I_{A} based on the first mantissa representation M_{A} and the first sign bit S_{A}. The second S-FP-DAC 504b is configured to receive a second control signal P_{B}, a second enable signal ENB, a second mantissa representation M_{B}, a second sign bit S_{B}, and a second clock signal CLK₂. The second S-FP-DAC 504b produces a second current output I_{B} based on the second mantissa representation M_{B} and the second sign bit S_{B}. Each of the first S-FP-DAC 504a and the second S-FP-DAC 504b comprises a positive current source bank and a negative current source bank, as described with reference to the signed floating-point digital-to-analog converter 104 of FIG. 1. The positive current source bank comprises a first plurality of binary-weighted current sources and the negative current source bank comprises a second plurality of binary-weighted current sources. Each of the first S-FP-DAC 504a and the second S-FP-DAC 504b further comprises a mantissa storage configured to store a respective mantissa representation, where bits of the respective mantissa representation selectively enable corresponding current sources in the positive current source bank and the negative current source bank to produce a positive current output and a negative current output, respectively. Each of the first S-FP-DAC 504a and the second S-FP-DAC 504b further comprises sign-controlled switches configured to route the positive current output or the negative current output to an output of the respective S-FP-DAC based on the respective sign bit to produce the respective signed current output.

The mantissa storage of each of the first S-FP-DAC 504a and the second S-FP-DAC 504b comprises a shift register configured to perform right-shift operations on bits of the respective mantissa representation based on clock signals. The right-shift operations shift a zero bit into a most significant bit position of the respective mantissa representation for each clock cycle of the clock signals. The shift register enables exponent alignment for floating-point addition operations by shifting the mantissa representation of the operand with the smaller exponent to account for exponent differences between operands. When adding two floating-point numbers, the exponents may be matched to the highest exponent, which results in mantissa shifting by the difference in exponents. Before addition, the operand with the smaller exponent may have its mantissa right-shifted by the exponent difference. For example, if the first floating-point operand has an exponent E_{A} and the second floating-point operand has an exponent E_{B}, and E_{A} is greater than or equal to E_{B}, then the mantissa of the second floating-point operand may be right-shifted by E_{A}−E_{B} bit positions before addition. The digital processing circuit 512 is configured to determine the exponent difference and generate the appropriate number of clock cycles to the shift register of the S-FP-DAC corresponding to the operand with the smaller exponent. The number of clock cycles applied to the shift register equals the exponent difference to perform the right-shift operations on the respective mantissa representation. By removing the clock signal and holding it static, the shifting of bits stops. As right shift occurs, least significant bits are discarded, resulting in lower precision representation of the same value.

As further shown in FIG. 5, the first current output I_{A} from the first S-FP-DAC 504a and the second current output I_{B} from the second S-FP-DAC 504b combine to form a combined current I_{A+B}. The combined current I_{A+B} flows through the pulse switch 506 to the integration circuit 508. The pulse switch 506 is controlled by the second sign bit S_{B} and connects to the integration circuit 508. The integration circuit 508 comprises a capacitor coupled to a bias voltage V_{Bias}. The integration circuit 508 accumulates charge from the combined current I_{A+B} to produce a voltage signal 516. The voltage signal 516 is proportional to the sum of the mantissas M_{A+B}. The voltage signal 516 is across the capacitor as a sum of charges accumulated from the flow of the first current output I_{A} and the second current output IR. The mathematical relationship for the addition operation may be expressed as

$${V}_{out} = \frac{( {I}_{A} + {I}_{B} ) \times T}{C} ,$$

where I_{A} represents the current magnitude from the first S-FP-DAC 504a, I_{B} represents the current magnitude from the second S-FP-DAC 504b, T represents the integration time, and C represents the capacitance value of the integration circuit 508. The signed current outputs from the first S-FP-DAC 504a and the second S-FP-DAC 504b may be positive or negative based on the respective sign bits, enabling the integration circuit 508 to accumulate both positive and negative contributions to produce the sum.

The analog-to-digital converter 510 receives the voltage signal 516 and is configured to convert the voltage signal 516 to a digital output V_{OUT} that is proportional to M_{A+B}. The analog-to-digital converter 510 produces a digital accumulated mantissa 518 designated as Y_{M} representing the result of the mantissa addition in digital form. The analog-to-digital converter 510 extracts extra bits to account for signed operations and overflow of the addition operation. The sign may be determined from current or voltage polarity (positive or negative). The digital processing circuit 512 receives the digital accumulated mantissa 518 from the analog-to-digital converter 510 and produces the accumulated output 520 designated as Y=A+B. The digital processing circuit 512 is configured to perform exponent computation and sign determination operations in the digital domain. The digital processing circuit 512 computes a result exponent based on the larger of the two input exponents and adjusts the result exponent based on any overflow or normalization of the digital accumulated mantissa 518. The digital processing circuit 512 determines a result sign based on a polarity of the digital accumulated mantissa 518, where a positive result corresponds to a result sign bit of zero and a negative result corresponds to a result sign bit of one. The digital processing circuit 512 reconstructs the accumulated output 520 in an IEEE floating-point format based on the result exponent, the result sign, and the normalized digital accumulated mantissa 518. The accumulated output 520 may be output in FP8 format, FP16 format, BF16 format, or other floating-point formats depending on the configuration of the floating-point adder circuit 502.

With continued reference to FIG. 5, the floating-point adder circuit 502 separates digital domain processing of exponents and sign bits from analog domain processing of mantissas. The exponent comparison, exponent difference calculation, and shift amount determination are performed entirely in the digital domain using simple comparison and subtraction operations. The mantissa addition is performed in the analog domain using the current sources of the first S-FP-DAC 504a and the second S-FP-DAC 504b, where the signed current outputs combine on the shared integration capacitor of the integration circuit 508. The analog-to-digital converter 510 provides the interface between the analog mantissa addition result and the digital reconstruction of the final accumulated output 520. In various embodiments, the floating-point adder circuit 502 may be extended to support addition of more than two floating-point operands by including additional S-FP-DACs arranged in parallel, similar to the configuration of the floating-point MAC circuit 302 of FIG. 3. When adding more than two values, the digital processing circuit 512 may determine the value with the lowest exponent among the set of operands, select a partial set of operands that have exponents close to one another, and process the partial set together while excluding operands with exponents outside the range. The digital processing circuit 512 may store intermediate sums in the digital domain and repeat the process until all operands are accounted for, with the final result computed as the sum of intermediate results using digital operations.

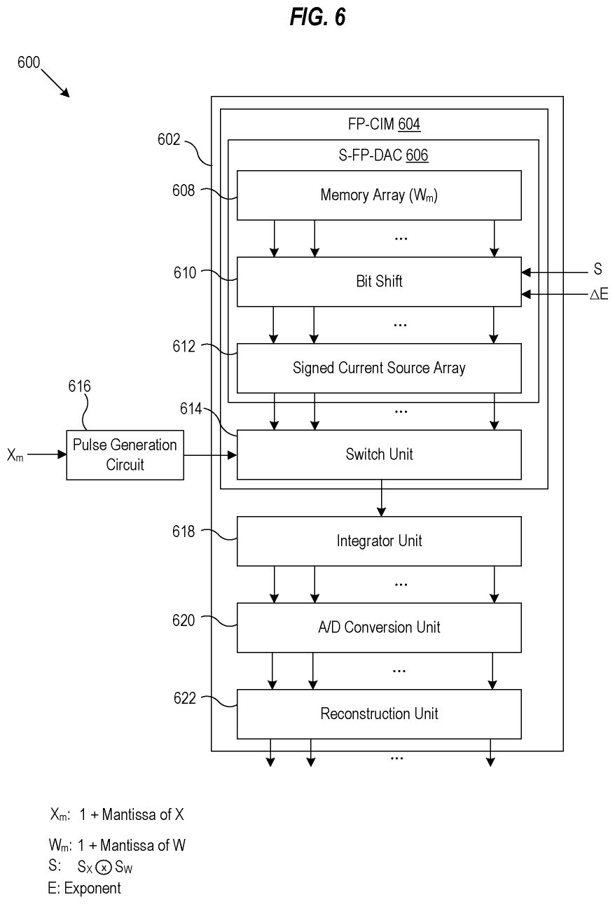

FIG. 6 is a block diagram 600 that illustrates a floating-point multiplier circuit 602 comprising a floating-point compute-in-memory circuit (FP-CIM) 604, in accordance with an embodiment of the disclosure. FIG. 6 is explained in conjunction with elements from FIG. 1, FIG. 2, FIG. 3, FIG. 4A, FIG. 4B, FIG. 4C, and FIG. 5. The floating-point multiplier circuit 602 is configured to perform floating-point multiplication operations using a compute-in-memory architecture that integrates memory storage with computational elements. The floating-point compute-in-memory circuit (FP-CIM) 604 contains multiple processing stages for performing floating-point multiplication operations, enabling computation to occur in close proximity to stored data and reducing data movement overhead between memory and processing units. In various embodiments, the floating-point multiplier circuit 602 may be deployed in neural network accelerators, digital signal processing systems, scientific computing systems, and other applications where high-throughput floating-point multiplication operations are required with reduced power consumption and latency.

The floating-point compute-in-memory circuit (FP-CIM) 604 comprises an S-FP-DAC 606 positioned at the top of the circuit hierarchy. The S-FP-DAC 606 is coupled to a memory array 608 that stores weight values Wₘ, where Wₘ represents 1 plus the mantissa of W. The memory array 608 provides stored mantissa values to subsequent processing stages within the floating-point compute-in-memory circuit (FP-CIM) 604. The weight values Wₘ stored in the memory array 608 include the implicit leading one bit prepended to the mantissa bits, as described with reference to the mantissa storage 108 of FIG. 1. In various embodiments, the memory array 608 may be implemented using static random-access memory (SRAM) cells, dynamic random-access memory (DRAM) cells, non-volatile memory elements such as resistive random-access memory (ReRAM), phase-change memory (PCM), magnetoresistive random-access memory (MRAM), or flash memory cells. The memory array 608 may store multiple weight values in parallel rows or columns to support vector or matrix multiplication operations.

With continued reference to FIG. 6, a bit shift 610 is positioned below the memory array 608 within the floating-point compute-in-memory circuit (FP-CIM) 604. The bit shift 610 is configured to perform shifting operations on the mantissa values retrieved from the memory array 608. The bit shift 610 receives inputs including S representing the sign computed as S_{X} XOR S_{W}, where S_{X} represents the sign bit of a first operand X and S_{W} represents the sign bit of a second operand W stored in the memory array 608. The bit shift 610 further receives an input ΔE representing the exponent difference for exponent alignment. The exponent difference ΔE is computed by the digital processing circuit (as shown in FIG. 1, for example) as the difference between a maximum exponent and a respective product exponent, as described with reference to the flowchart 400 of FIGS. 4A, 4B, and 4C. The bit shift 610 enables exponent alignment by shifting mantissa bits based on the exponent difference between operands, similar to the shift register 110 described with reference to FIG. 1. The bit shift 610 performs right-shift operations on the mantissa values, shifting a zero bit into a most significant bit position for each shift position. The number of shift positions equals the exponent difference ΔE. In various embodiments, the bit shift 610 may be implemented using a shift register that performs the shift operation over multiple clock cycles, or using a barrel shifter that performs the shift operation in a single clock cycle.

The bit shift 610 is coupled to a signed current source array 612 within the floating-point compute-in-memory circuit (FP-CIM) 604. The signed current source array 612 converts the shifted mantissa values into corresponding current signals based on the sign information provided by the S input. The signed current source array 612 comprises a positive current source bank and a negative current source bank, as described with reference to the positive current source bank 106a and the negative current source bank 106b of FIG. 1. The positive current source bank comprises a first plurality of binary-weighted current sources and the negative current source bank comprises a second plurality of binary-weighted current sources. Bits of the shifted mantissa values selectively enable corresponding current sources in the positive current source bank and the negative current source bank to produce a positive current output and a negative current output, respectively. The signed current source array 612 further comprises sign-controlled switches configured to route the positive current output or the negative current output based on the sign information S. When the sign S equals zero, indicating a positive product, the sign-controlled switches route the positive current output. When the sign S equals one, indicating a negative product, the sign-controlled switches route the negative current output. The signed current source array 612 produces signed current signals that represent the signed mantissa values of the operands.

As further shown in FIG. 6, a switch unit 614 is coupled to the signed current source array 612 within the floating-point compute-in-memory circuit (FP-CIM) 604. The switch unit 614 controls the flow of current signals from the signed current source array 612 to subsequent stages. The switch unit 614 receives control signals from a pulse generation circuit (PGC) 616 positioned outside the floating-point compute-in-memory circuit (FP-CIM) 604. The PGC 616 receives an input Xₘ representing 1 plus the mantissa of X, where X represents a first floating-point operand. The input Xₘ comprises the implicit leading one bit prepended to the mantissa bits of the first floating-point operand, consistent with the mantissa representation described with reference to the pulse generation circuit 120 of FIG. 1. The PGC 616 generates timing signals that control the duration of current integration. The timing signals have a duration proportional to the input Xₘ, expressed as Xₘ× Tᵤ, where Tᵤ represents a unit time value. The timing signals from the PGC 616 enable the switch unit 614 to allow the flow of signed current signals from the signed current source array 612 for the duration of the timing signals. The switch unit 614 functions similarly to the pulse switch 118 described with reference to FIG. 1, controlling the flow of current to the integration stage based on the pulse duration.

An integrator unit 618 is coupled to the switch unit 614 within the floating-point compute-in-memory circuit (FP-CIM) 604. The integrator unit 618 accumulates charge from the current signals over the duration controlled by the PGC 616. The integrator unit 618 produces a voltage signal proportional to the product of the mantissa representations. The mathematical relationship for the integration operation may be expressed as Vₒᵤₜ=(I× T)/C, where I represents the current magnitude determined by the shifted mantissa value from the signed current source array 612, T represents the pulse duration determined by the input Xₘ from the PGC 616, and C represents the capacitance value of the integrator unit 618. The integrator unit 618 functions similarly to the integration circuit 122 described with reference to FIG. 1, comprising a capacitor that accumulates charge from the flow of signed current signals for the duration of the timing signals. In various embodiments, the integrator unit 618 may be implemented using a passive capacitor-based integrator or an operational amplifier-based integrator.

With continued reference to FIG. 6, an A/D conversion unit 620 is coupled to the integrator unit 618 within the floating-point compute-in-memory circuit (FP-CIM) 604. The A/D conversion unit 620 converts the analog voltage signal from the integrator unit 618 to a digital representation. The A/D conversion unit 620 provides the digital mantissa product to a reconstruction unit 622. The A/D conversion unit 620 functions similarly to the analog-to-digital converter (ADC) 124 described with reference to FIG. 1, converting the voltage signal to a digital mantissa product representing the result of the mantissa multiplication in digital form. The A/D conversion unit 620 extracts extra bits to account for signed operations and overflow conditions. In various embodiments, the A/D conversion unit 620 may be implemented using successive approximation register (SAR) ADCs, sigma-delta ADCs, flash ADCs, or pipeline ADCs, depending on speed, precision, and power consumption requirements.

The reconstruction unit 622 receives the digital output from the A/D conversion unit 620 and reconstructs the complete floating-point product by combining the digital mantissa product with the computed exponent and sign information. The reconstruction unit 622 functions similarly to the digital processing circuit 126 described with reference to FIG. 1. The reconstruction unit 622 is configured to compute a product exponent by adding a first exponent of the first floating-point operand X and a second exponent of the second floating-point operand W stored in the memory array 608, and apply bias correction to the product exponent to obtain an updated product exponent. The reconstruction unit 622 receives the sign information S computed as S_{X} XOR S_{W} from the bit shift 610, which represents the product sign bit. The reconstruction unit 622 is configured to reconstruct the floating-point product in an IEEE floating-point format based on the updated product exponent, the product sign bit, and the digital mantissa product from the A/D conversion unit 620. The reconstruction unit 622 may perform normalization of the digital mantissa product and adjust the updated product exponent based on the normalization, and handle overflow or underflow conditions. The floating-point multiplier circuit 602 separates digital domain processing of exponents and sign bits from analog domain processing of mantissas, with the exponent computation and sign calculation performed entirely in the digital domain and the mantissa multiplication performed in the analog domain using the current sources and pulse-width modulation techniques of the floating-point compute-in-memory circuit (FP-CIM) 604.

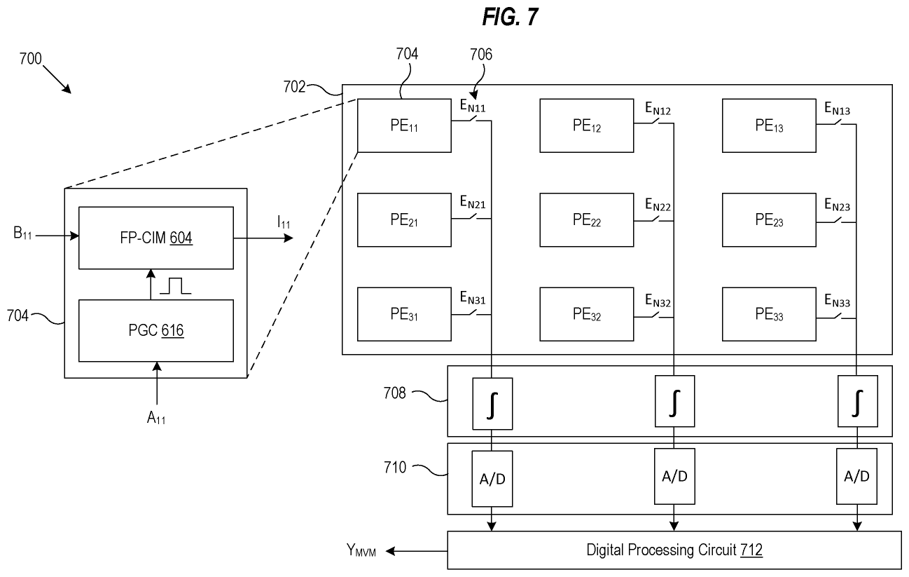

FIG. 7 is a diagram 700 that illustrates a floating-point MVM circuit 702 configured to perform matrix-vector multiplication operations on floating-point operands, in accordance with an embodiment of the disclosure. FIG. 7 is explained in conjunction with elements from FIG. 1, FIG. 2, FIG. 3, FIG. 4A, FIG. 4B, FIG. 4C, FIG. 5, and FIG. 6. The floating-point MVM circuit 702 comprises a plurality of processing elements arranged in a two-dimensional array configuration, an integration unit 708, an analog-to-digital converter unit 710, and a digital processing circuit 712. The floating-point MVM circuit 702 is configured to perform matrix-vector multiplication operations where a matrix of weight values is multiplied by a vector of input values to produce a vector of output values. In various embodiments, the floating-point MVM circuit 702 may be deployed in neural network accelerators for inference and training applications, digital signal processing systems, scientific computing systems, and other applications where high-throughput matrix-vector multiplication operations are required.

The plurality of processing elements includes a first processing element PE₁₁, a second processing element PE₁₂, a third processing element PE₁₃, a fourth processing element PE₂₁, a fifth processing element PE₂₂, a sixth processing element PE₂₃, a seventh processing element PE₃₁, an eighth processing element PE₃₂, and a ninth processing element PE₃₃. The processing elements are arranged in a three-by-three array configuration. The first processing element PE₁₁, the second processing element PE₁₂, and the third processing element PE₁₃ form a first row of the array. The fourth processing element PE₂₁, the fifth processing element PE₂₂, and the sixth processing element PE₂₃ form a second row of the array. The seventh processing element PE₃₁, the eighth processing element PE₃₂, and the ninth processing element PE₃₃ form a third row of the array. In various embodiments, the floating-point MVM circuit 702 may include larger array configurations such as 4×4, 8×8, 16×16, 32×32, 64×64, or other array sizes to support different matrix dimensions and computational throughput requirements. The two-dimensional array configuration enables parallel processing of multiple multiplication operations, with each processing element performing a multiplication of a weight value and an input value.

Each processing element of the plurality of processing elements receives a respective enable signal for controlling participation in the computation. The first processing element PE₁₁ receives a first enable signal EN₁₁. The second processing element PE₁₂ receives a second enable signal EN₁₂. The third processing element PE₁₃ receives a third enable signal EN₁₃. The fourth processing element PE₂₁ receives a fourth enable signal EN₂₁. The fifth processing element PE₂₂ receives a fifth enable signal EN₂₂. The sixth processing element PE₂₃ receives a sixth enable signal EN₂₃. The seventh processing element PE₃₁ receives a seventh enable signal EN₃₁. The eighth processing element PE₃₂ receives an eighth enable signal EN₃₂. The ninth processing element PE₃₃ receives a ninth enable signal EN₃₃. The respective enable signals control whether each processing element participates in the current computation and outputs current to the integration unit 708. When a respective enable signal equals one, the corresponding processing element participates in the operation and outputs current. When a respective enable signal equals zero, the corresponding processing element does not participate in the operation and does not output any current. The enable signals enable selective activation of processing elements based on exponent grouping during matrix-vector multiplication operations, as described with reference to the flowchart 400 of FIGS. 4A, 4B, and 4C.

With continued reference to FIG. 7, each processing element of the plurality of processing elements comprises a floating-point compute-in-memory circuit (FP-CIM) 604 including an S-FP-DAC 704 and a PGC 616. The floating-point compute-in-memory circuit (FP-CIM) 604 is configured to perform floating-point multiplication operations using a compute-in-memory architecture, as described with reference to FIG. 6. The S-FP-DAC 704 comprises a positive current source bank and a negative current source bank, a mantissa storage configured to store a mantissa representation, sign-controlled switches configured to route a positive current output or a negative current output based on a sign bit, and an enable switch configured to selectively connect or disconnect a signed current output based on the respective enable signal. The PGC 616 is configured to generate timing signals that control the duration of current integration based on a mantissa of a second operand. The first processing element PE₁₁ is shown in expanded detail in FIG. 7, illustrating the internal structure comprising the floating-point compute-in-memory circuit (FP-CIM) 604 with the S-FP-DAC 704 and the PGC 616.

The first processing element PE₁₁ receives a first operand A₁₁ and a second operand B₁₁ as inputs. The first operand A₁₁ is provided to the S-FP-DAC 704 of the first processing element PE₁₁. The first operand A₁₁ comprises a sign bit, an exponent, and a mantissa of a first floating-point value. The S-FP-DAC 704 stores a mantissa representation of the first operand A₁₁ comprising an implicit leading one bit prepended to the mantissa bits, and produces a signed current output based on the sign bit and the mantissa representation. The second operand B₁₁ is provided to the PGC 616 of the first processing element PE₁₁. The second operand B₁₁ comprises a sign bit, an exponent, and a mantissa of a second floating-point value. The PGC 616 generates a timing signal having a duration proportional to a mantissa representation of the second operand B₁₁ comprising an implicit leading one bit prepended to the mantissa bits. The first processing element PE₁₁ produces a combined current output I₁₁ that represents the product of the mantissa representations of the first operand A₁₁ and the second operand B₁₁. The combined current output I₁₁ is a signed current that may be positive or negative based on the product sign computed as the exclusive-OR of the sign bits of the first operand A₁₁ and the second operand B₁₁. Each of the other processing elements (the second processing element PE₁₂ through the ninth processing element PE₃₃) operates similarly, receiving respective first and second operands and producing respective combined current outputs.

As further shown in FIG. 7, the processing elements in each column are connected to share current outputs along column lines. The current outputs from the first processing element PE₁₁, the fourth processing element PE₂₁, and the seventh processing element PE₃₁ in a first column combine and flow to a first integration circuit of the integration unit 708. The current outputs from the second processing element PE₁₂, the fifth processing element PE₂₂, and the eighth processing element PE₃₂ in a second column combine and flow to a second integration circuit of the integration unit 708. The current outputs from the third processing element PE₁₃, the sixth processing element PE₂₃, and the ninth processing element PE₃₃ in a third column combine and flow to a third integration circuit of the integration unit 708. The column-wise current sharing enables accumulation of products along each column, which corresponds to computing a dot product of a column of the weight matrix with the input vector. The combined current outputs from processing elements in the same column sum on a shared column line before reaching the integration unit 708.

The integration unit 708 comprises three parallel integration circuits, each corresponding to a column of the processing element array. Each integration circuit of the integration unit 708 comprises a capacitor-based integration circuit that accumulates charges from the combined current outputs of the processing elements in the respective column. Each integration circuit of the integration unit 708 accumulates charges from the combined current outputs to produce a voltage signal proportional to an accumulated product of pairwise mantissas. The mathematical relationship for the accumulated voltage in each column may be expressed as

$${V}_{out , j} = {\sum }_{i = 1}^{N} \frac{{I}_{ij} \times {T}_{ij}}{C} ,$$

where V_{out,j} represents the output voltage for the j-th column, Iᵢⱼ represents the current magnitude from the processing element in the i-th row and j-th column, Tᵢⱼ represents the pulse duration from the processing element in the i-th row and j-th column, C represents the capacitance value, and N represents the number of rows in the array. The integration unit 708 produces three voltage signals, one for each column, representing the accumulated products of pairwise mantissas for each column of the matrix-vector multiplication.

With continued reference to FIG. 7, the analog-to-digital converter unit 710 comprises three parallel analog-to-digital converters, each coupled to a respective integration circuit of the integration unit 708. Each analog-to-digital converter of the analog-to-digital converter unit 710 is configured to convert the voltage signal from the respective integration circuit to a digital accumulated mantissa product. The analog-to-digital converter unit 710 extracts extra bits to account for signed operations and overflow conditions. The sign of each accumulated result may be determined from the polarity of the respective voltage signal (positive or negative). The analog-to-digital converter unit 710 produces three digital accumulated mantissa products, one for each column of the matrix-vector multiplication, representing the results of the mantissa accumulations in digital form.

The digital processing circuit 712 receives the digital outputs from the analog-to-digital converter unit 710 and processes the digital accumulated mantissa products to produce a matrix-vector multiplication output Y_{MVM}. The digital processing circuit 712 performs exponent computation, sign determination, normalization, and result reconstruction operations in the digital domain to produce the final floating-point matrix-vector multiplication result. The digital processing circuit 712 is configured to compute product exponents for each multiplication pair by adding respective first exponents and respective second exponents, determine maximum exponents for each column accumulation, generate clock signals for shift registers in each S-FP-DAC 704 based on differences between maximum exponents and respective product exponents, and generate enable signals for each processing element based on exponent grouping. The digital processing circuit 712 is further configured to normalize each digital accumulated mantissa product and adjust the respective maximum exponent based on the normalization, determine a result sign for each column based on the polarity of the respective digital accumulated mantissa product, and reconstruct each element of the matrix-vector multiplication output Y_{MVM} in an IEEE floating-point format based on the adjusted maximum exponent, the result sign, and the normalized digital accumulated mantissa product. The matrix-vector multiplication output Y_{MVM} comprises a vector of floating-point values, with each element corresponding to a column of the processing element array. The floating-point MVM circuit 702 separates digital domain processing of exponents and sign bits from analog domain processing of mantissas, with the exponent computation, sign calculation, grouping decisions, and result reconstruction performed entirely in the digital domain and the mantissa multiplication and accumulation performed in the analog domain using the current sources and pulse-width modulation techniques of the processing elements.

Reference throughout this specification to “an example” means that a particular feature, structure, or characteristic described in connection with the example is included in at least one embodiment of the present invention. Thus, appearances of the phrase “in an example” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on its presentation in a common group without indications to the contrary. In addition, various embodiments and examples of the present invention may be referred to herein along with alternatives for the various components thereof. It is understood that such embodiments, examples, and alternatives are not to be construed as de facto equivalents of one another but are to be considered as separate and autonomous representations of the present invention.

Although the foregoing has been described in some detail for purposes of clarity, it will be apparent that certain changes and modifications may be made without departing from the principles thereof. It should be noted that there are many alternative ways of implementing both the processes and apparatuses described herein. Accordingly, the present embodiments are to be considered illustrative and not restrictive, and the invention is not to be limited to the details given herein but may be modified within the scope and equivalents of the appended claims.

Those having skill in the art will appreciate that many changes may be made to the details of the above-described embodiments without departing from the underlying principles of the invention. The scope of the present invention should, therefore, be determined only by the following claims.

What is claimed is:

1. A floating-point multiplier circuit, comprising:
a signed floating-point digital-to-analog converter (S-FP-DAC) configured to receive a first sign bit and a first mantissa of a first floating-point operand, wherein the S-FP-DAC comprises:
a positive current source bank having a first plurality of binary-weighted current sources;
a negative current source bank having a second plurality of binary-weighted current sources;
a mantissa storage configured to store a first mantissa representation of the first mantissa, wherein bits of the first mantissa representation selectively enable corresponding current sources in each of the positive current source bank and the negative current source bank to produce a positive current output and a negative current output, respectively; and
sign-controlled switches configured to route the positive current output or the negative current output to an output of the S-FP-DAC based on the first sign bit to produce a signed current output;
a pulse switch coupled to an output of the S-FP-DAC;
a pulse generation circuit configured to generate a pulse signal having a duration proportional to a second mantissa representation of a second mantissa of a second floating-point operand, wherein the pulse signal enables the pulse switch to allow a flow of the signed current output for the duration;
an integration circuit coupled to the pulse switch, wherein the integration circuit accumulates a charge from the flow of the signed current output for the duration to produce a voltage signal proportional to a product of the first mantissa representation and the second mantissa representation; and
an analog-to-digital converter (ADC) configured to convert the voltage signal to a digital mantissa product.

2. The floating-point multiplier circuit of claim 1, wherein the first mantissa representation comprises an implicit leading one bit prepended to the first mantissa, and the second mantissa representation comprises an implicit leading one bit prepended to the second mantissa.

3. The floating-point multiplier circuit of claim 1, further comprising a digital processing circuit configured to:
compute a product exponent by adding a first exponent of the first floating-point operand and a second exponent of the second floating-point operand; and
apply a bias correction to the product exponent to obtain updated product exponent.

4. The floating-point multiplier circuit of claim 3, wherein the digital processing circuit is further configured to perform an exclusive-OR operation on the first sign bit and a second sign bit of the second floating-point operand to compute a product sign bit.

5. The floating-point multiplier circuit of claim 4, wherein the digital processing circuit is further configured to reconstruct a floating-point product of the first floating-point operand and the second floating-point operand in an IEEE floating-point format based on the updated product exponent, the product sign bit, and the digital mantissa product.

6. The floating-point multiplier circuit of claim 1, wherein the integration circuit comprises a capacitor coupled between the pulse generation circuit and a reference ground terminal, and the voltage signal is across the capacitor.

7. The floating-point multiplier circuit of claim 1, wherein each of the first floating-point operand and the second floating-point operand is a binary number that follows IEEE 754 standard.

8. The floating-point multiplier circuit of claim 1, wherein the sign-controlled switches are configured to:
route the positive current output to the output of the S-FP-DAC based on the first sign bit indicating a positive value of the first floating-point operand; and
route the negative current output to the output of the S-FP-DAC based on the first sign bit indicating a negative value of the first floating-point operand.

9. The floating-point multiplier circuit of claim 1, wherein the second mantissa representation is an unsigned mantissa representation, and the sign-controlled switches are further configured to route the positive current output or the negative current output based on a second sign bit of the second floating-point operand.

10. A floating-point multiply-accumulate (MAC) circuit, comprising:
a plurality of signed floating-point digital-to-analog converters (S-FP-DACs), wherein each S-FP-DAC of the plurality of S-FP-DACs is configured to:
receive a respective first sign bit and a respective first mantissa of a respective first floating-point operand of a first operand set; and
produce a respective signed current output based on the respective first sign bit and the respective first mantissa;
a plurality of pulse switches, wherein each pulse switch of the plurality of pulse switches is coupled to an output of a respective S-FP-DAC of the plurality of S-FP-DACs;
a plurality of pulse generation circuits, wherein each pulse generation circuit of the plurality of pulse generation circuits is configured to generate a respective pulse signal based on a respective second mantissa of a respective second floating-point operand of a second operand set, and wherein each respective pulse signal enables a respective pulse switch of the plurality of pulse switches to allow a flow of the respective signed current output for a respective duration;
an integration circuit coupled to the plurality of pulse switches, wherein the integration circuit accumulates charges from the flow of the respective signed current output of each S-FP-DAC of the plurality of S-FP-DACs for the respective duration to produce a voltage signal proportional to an accumulated product of pairwise mantissas of the first operand set and the second operand set; and
an analog-to-digital converter (ADC) configured to convert the voltage signal to a digital accumulated mantissa product.

11. The floating-point MAC circuit of claim 10, wherein each S-FP-DAC of the plurality of S-FP-DACs comprises a positive current source bank and a negative current source bank.

12. The floating-point MAC circuit of claim 11, wherein the positive current source bank comprises a first plurality of binary-weighted current sources and the negative current source bank comprises a second plurality of binary-weighted current sources.

13. The floating-point MAC circuit of claim 11, wherein each S-FP-DAC of the plurality of S-FP-DACs comprises a mantissa storage configured to store a respective first mantissa representation of the respective first mantissa, wherein bits of the respective first mantissa representation selectively enable corresponding current sources in the positive current source bank and the negative current source bank to produce a positive current output and a negative current output, respectively.

14. The floating-point MAC circuit of claim 13, wherein the respective first mantissa representation comprises an implicit leading one bit prepended to bits of the respective first mantissa.

15. The floating-point MAC circuit of claim 13, wherein each S-FP-DAC of the plurality of S-FP-DACs comprises sign-controlled switches configured to route the positive current output or the negative current output to the output of the respective S-FP-DAC based on the respective first sign bit to produce the respective signed current output.

16. The floating-point MAC circuit of claim 15, wherein the mantissa storage comprises a shift register configured to perform right-shift operations on the bits of the respective first mantissa representation based on clock signals, and wherein the right-shift operations shift a zero bit into a most significant bit position of the respective first mantissa representation for each clock cycle of the clock signals.

17. The floating-point MAC circuit of claim 16, further comprising a digital processing circuit configured to:
compute each product exponent of a plurality of respective product exponents for a pair of the respective first floating-point operand and the respective second floating-point operand by adding a respective first exponent of the respective first floating-point operand and a respective second exponent of the respective second floating-point operand;
determine a maximum exponent among the plurality of respective product exponents; and
generate the clock signals for each S-FP-DAC of the plurality of S-FP-DACs based on a difference between the maximum exponent and a respective product exponent of the plurality of respective product exponents.

18. The floating-point MAC circuit of claim 17, wherein the digital processing circuit is further configured to apply a number of clock cycles of the clock signals to each S-FP-DAC of the plurality of S-FP-DACs, wherein the number of clock cycles equals the difference between the maximum exponent and the respective product exponent for the respective S-FP-DAC.

19. The floating-point MAC circuit of claim 17, wherein the digital processing circuit is further configured to:
perform an exclusive-OR operation on the respective first sign bit and a respective second sign bit of the respective second floating-point operand to compute a respective product sign bit for the respective first floating-point operand and the respective second floating-point operand;
generate a respective control signal for each S-FP-DAC of the plurality of S-FP-DACs based on the respective product sign bit, wherein the sign-controlled switches of each S-FP-DAC are configured to selectively invert routing of the positive current output and the negative current output based on the respective control signal.

20. The floating-point MAC circuit of claim 17, wherein each S-FP-DAC of the plurality of S-FP-DACs further comprises an enable switch configured to selectively connect or disconnect the respective signed current output from the integration circuit based on a respective enable signal.

21. The floating-point MAC circuit of claim 20, wherein the digital processing circuit is further configured to:
group the plurality of S-FP-DACs into a plurality of groups based on the plurality of respective product exponents, wherein each group of the plurality of groups comprises a subset of S-FP-DACs of the plurality of S-FP-DACs, and the subset of S-FP-DACs have respective product exponents within a predetermined range; and
generate the respective enable signal for each S-FP-DAC of the plurality of S-FP-DACs to enable the subset of S-FP-DACs and disable S-FP-DACs of the plurality of S-FP-DACs different from the subset of S-FP-DACs.

22. The floating-point MAC circuit of claim 10, wherein:
the respective pulse signal is generated with a respective pulse duration proportional to a respective second mantissa representation of the respective second mantissa,
the respective second mantissa representation is an unsigned value, and
the respective second mantissa representation comprises an implicit leading one bit prepended to bits of the respective second mantissa.

23. The floating-point MAC circuit of claim 10, wherein the integration circuit comprises a capacitor and the voltage signal is across the capacitor as a sum of charges accumulated from the flow of the respective signed current output of each S-FP-DAC of the plurality of S-FP-DACs for the respective duration.
